(19) United States
(12) Patent Application Publication
(10) Pub. No.: US 2026/0206216 A1
(43) Pub. Date: Jul. 16, 2026

(54) SEMICONDUCTOR DEVICES AND FABRICATING METHODS THEREOF

(71) Applicant: Yangtze Memory Technologies Co., Ltd., Wuhan (CN)

(72) Inventors: Xiaolong Du, Wuhan (CN); Zhiliang Xia, Wuhan (CN); Wei Liu, Wuhan (CN); Zongliang Huo, Wuhan (CN)

(21) Appl. No.: 19/055,727

(22) Filed: Feb. 18, 2025

(30) Foreign Application Priority Data
Jan. 15, 2025 (CN) 202510066568.1

(51) Int. Cl. H10B 12/00; H01L 23/00; H01L 25/065; H10B 80/00

(52) U.S. Cl. CPC H10B 12/50; H10B 12/0335; H10B 12/09; H10B 80/00; H10W 90/00; H10W 90/20; H10W 90/792

(57) ABSTRACT

A disclosed semiconductor device includes a first semiconductor structure, a second semiconductor structure, and a third semiconductor structure. The first semiconductor structure includes first memory cells each having a first transistor and a first storage unit coupled to the first transistor. The second semiconductor structure includes second memory cells each having a second transistor and a second storage unit coupled to the second transistor. The third semiconductor structure is located between the first semiconductor structure and the second semiconductor structure in a first direction. The third semiconductor structure includes a first peripheral circuit structure formed on a semiconductor layer and coupled to the first semiconductor structure and a second peripheral circuit structure formed on the semiconductor layer and coupled to the second semiconductor structure.

### CROSS-REFERENCE TO RELATED APPLICATIONS

This application claims the benefit of priority to Chinese Application No. 202510066568.1, filed on Jan. 15, 2025, which is incorporated herein by reference in its entirety.

### TECHNICAL FIELD

The present disclosure generally relates to the field of semiconductor technology, and more particularly, to semiconductor devices and fabricating methods thereof.

### BACKGROUND

Planar memory cells are scaled to smaller sizes by improving process technology, circuit design, programming algorithm, and fabrication process. However, as feature sizes of the memory cells approach a lower limit, planar process, and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuit structures for facilitating operations of the memory array.

### SUMMARY

Some aspects of the present disclosure provide a semiconductor device including a first semiconductor structure, a second semiconductor structure, and a third semiconductor structure. The first semiconductor structure includes first memory cells each having a first transistor and a first storage unit coupled to the first transistor. The second semiconductor structure includes second memory cells each having a second transistor and a second storage unit coupled to the second transistor. The third semiconductor structure is located between the first semiconductor structure and the second semiconductor structure in a first direction. The third semiconductor structure includes a first peripheral circuit structure formed on a semiconductor layer and coupled to the first semiconductor structure and a second peripheral circuit structure formed on the semiconductor layer and coupled to the second semiconductor structure.

In some implementations, the first peripheral circuit structure is formed on a first side of the semiconductor layer, and the second peripheral circuit structure is formed on a second side of the semiconductor layer. The second side of the semiconductor layer is opposite to the first side of the semiconductor layer.

In some implementations, the first semiconductor structure further includes a plurality of first contacts coupled between the first peripheral circuit structure and the first memory cells; and the second semiconductor structure further includes a plurality of second contacts coupled between the second peripheral circuit structure and the second memory cells. The first contacts and the second contacts are misaligned along the first direction.

In some implementations, the first peripheral circuit structure and the second peripheral circuit structure are formed on a first side of the semiconductor layer.

In some implementations, the first semiconductor structure further includes a plurality of first contacts coupled between the first memory cells and the first peripheral circuit structure; the second semiconductor structure further includes a plurality of second contacts coupled with the second memory cells. The third semiconductor structure further includes a plurality of vias throughout the semiconductor layer and coupled between the second contacts and the second peripheral circuit structure. The first contacts and the second contacts are misaligned along the first direction.

In some implementations, the semiconductor device includes a plurality of first contacts coupled between the first semiconductor structure and the third semiconductor structure. A first lateral dimension of a first end of the first contacts away from the third semiconductor structure is greater than a second lateral dimension of a second end of the first contacts close to the third semiconductor structure.

In some implementations, the semiconductor device further includes a first bonding structure located between the first semiconductor structure and the third semiconductor structure and a plurality of first contacts coupled between the first semiconductor structure and the first bonding structure. A first lateral dimension of a first end of the first contacts away from first bonding structure is smaller than a second lateral dimension of a second end of the first contacts close to the first bonding structure.

In some implementations, the semiconductor device includes a second bonding structure located between the second semiconductor structure and the third semiconductor structure and a plurality of second contacts coupled between the second semiconductor structure and the second bonding structure. A first lateral dimension of a first end of the second contacts away from the second bonding structure is smaller than a second lateral dimension of a second end of the second contacts close to the second bonding structure.

In some implementations, the first transistor or the second transistor includes a channel layer extending along the first direction and a gate structure coupled to the channel layer, and a leakage value of the channel layer is lower than a pico-ampere.

In some implementations, a thickness of the channel layer in a second direction is smaller than a width of the channel layer in a third direction, the first direction, the second direction, and the third direction are perpendicular to each other.

In some implementations, a ratio between the width of the channel layer and the thickness of the channel layer ranges from 10 to 500.

In some implementations, the first transistor or the second transistor is a single-gate transistor in which the gate structure of the single-gate transistor is located at one side of the channel layer in a plan view. The channel layer includes a first portion extending along the first direction and a second portion extending from an end of the first portion along a second direction. The second portion is coupled with a corresponding storage unit, the first direction and the second direction are perpendicular to each other.

In some implementations, the semiconductor device further includes a pad-out interconnect layer on the first semiconductor structure or the second semiconductor structure, the pad-out interconnect layer is coupled with the first peripheral circuit structure and the second peripheral circuit structure through a plurality of third contacts.

In some implementations, the first storage unit is located between the first transistor and the third semiconductor structure along the first direction. The second storage unit is located between the second transistor and the third semiconductor structure along the first direction.

In some implementations, the first transistor is located between the first storage unit and the third semiconductor structure along the first direction and the second transistor is located between the second storage unit and the third semiconductor structure along the first direction.

In some implementations, the first transistor is located between the first storage unit and the third semiconductor structure along the first direction. The second storage unit is located between the second transistor and the third semiconductor structure along the first direction.

Some aspects of the present disclosure provide a method for forming a semiconductor memory device, the method includes: forming a third semiconductor structure including a first peripheral circuit structure and a second peripheral circuit structure on a semiconductor layer; forming a first semiconductor structure including first memory cells each having a first transistor and a first storage unit coupled to the first transistor, the first semiconductor structure being coupled to the first peripheral circuit structure; and forming a second semiconductor structure including second memory cells each having a second transistor and a second storage unit coupled to the second transistor, the second semiconductor structure being coupled to the second peripheral circuit structure. The third semiconductor structure is located between the first semiconductor structure and the second semiconductor structure in a first direction.

In some implementations, forming the first semiconductor structure includes forming a first inter-structure isolation layer on a first side of the semiconductor layer; forming the first memory cells on the first inter-structure isolation layer; and forming a plurality of first contacts coupled between the first memory cells and the first peripheral circuit structure.

In some implementations, forming the first memory cells includes: forming the first storage unit; and forming the first transistor coupled with the first storage unit and stacked with the first storage unit along the first direction. The first transistor is formed before or after forming the first storage unit.

In some implementations, forming the second semiconductor structure includes forming a carrier substrate on the first semiconductor structure; and thinning the semiconductor layer through a second side of the semiconductor layer.

In some implementations, forming the second semiconductor structure includes forming a second inter-structure isolation layer on a second side of the semiconductor layer; forming the second memory cells on the second inter-structure isolation layer; and forming a plurality of second contacts coupled between the second memory cells and the second peripheral circuit structure. The first contacts and the second contacts are misaligned along the first direction.

In some implementations, forming the second memory cells includes: forming the second storage unit; and forming the second transistor coupled with the second storage unit and stacked with the second storage unit along the first direction. The second transistor is formed before or after forming the second storage unit.

In some implementations, the semiconductor layer is formed on a third substrate, and forming the second semiconductor structure includes forming the second semiconductor structure on a second substrate.

In some implementations, forming the second semiconductor structure further includes bonding the second substrate with a second side of the third substrate to form a second bonding structure.

In some implementations, forming the first semiconductor structure includes forming the first semiconductor structure on a first substrate.

In some implementations, the semiconductor layer is formed on a third substrate, and forming the first semiconductor structure further includes bonding the first substrate with a first side of the third substrate through a plurality of first bonding contacts to form a first bonding structure.

In some implementations, forming the second semiconductor structure includes forming the second semiconductor structure on a second substrate.

In some implementations, forming the second semiconductor structure further includes bonding the second substrate with a second side of the third substrate through a plurality of second bonding contacts to form a second bonding structure.

In some implementations, forming the second semiconductor structure includes forming a carrier substrate on the first semiconductor structure and thinning the third substrate through a second side of the third substrate.

In some implementations, forming the second semiconductor structure includes forming a second inter-structure isolation layer on a second side of the third substrate; forming the second semiconductor structure on the second inter-structure isolation layer; and forming a plurality of second contacts to couple the second semiconductor structure with the second peripheral circuit structure.

In some implementations, forming the first peripheral circuit structure and the second peripheral circuit structure on the semiconductor layer includes forming the first peripheral circuit structure on a first side of the semiconductor layer and forming the second peripheral circuit structure on a second side of the semiconductor layer.

In some implementations, forming the first peripheral circuit structure and the second peripheral circuit structure on the semiconductor layer includes forming the first peripheral circuit structure and the second peripheral circuit structure on a first side of the semiconductor layer and forming a plurality of vias throughout the semiconductor layer and coupled between the second peripheral circuit structure and the second semiconductor structure.

In some implementations, the method further includes forming a pad-out interconnect layer on the first semiconductor structure or the second semiconductor structure and coupling the pad-out interconnect layer with the first peripheral circuit structure and the second peripheral circuit structure through a plurality of third contacts.

Some aspects of the present disclosure provide a semiconductor device including a first semiconductor structure including a first array of memory cells; a second semiconductor structure including a second memory cells; and a third semiconductor structure located between the first semiconductor structure and the second semiconductor structure in a first direction. The third semiconductor structure includes a third substrate, a first peripheral circuit structure on the third substrate and coupled to the first semiconductor structure, and a second peripheral circuit structure on the third substrate and coupled to the second semiconductor structure.

In some implementations, the first peripheral circuit structure is formed on a first side of the third substrate and the second peripheral circuit structure is formed on a second side of the third substrate.

In some implementations, the method further includes a first interconnecting layer configured to couple the first semiconductor structure with the first peripheral circuit structure. The first interconnecting layer is located on the first side of the third substrate and is facing to the first semiconductor structure.

In some implementations, the first peripheral circuit structure and the second peripheral circuit structure are formed on a first side of the third substrate; and the third semiconductor structure further includes a plurality of vias throughout the third substrate and coupled with the second peripheral circuit structure.

In some implementations, the method further includes a plurality of first contacts coupled between the first semiconductor structure and the third semiconductor structure. A first lateral dimension of a first end of the first contacts away from the third semiconductor structure is greater than a second lateral dimension of a second end of the first contacts close to the third semiconductor structure.

In some implementations, the method further includes a first bonding structure located between the first semiconductor structure and the third semiconductor structure and a plurality of first contacts coupled between the first semiconductor structure and the first bonding structure. A first lateral dimension of a first end of the first contacts away from first bonding structure is smaller than a second lateral dimension of a second end of the first contacts close to the first bonding structure.

In some implementations, the method further includes a second bonding structure located between the second semiconductor structure and the third semiconductor structure and a plurality of second contacts coupled between the second semiconductor structure and the second bonding structure. A first lateral dimension of a first end of the second contacts away from the second bonding structure is smaller than a second lateral dimension of a second end of the second contacts close to the second bonding structure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1A illustrates a schematic circuit diagram of a semiconductor device including an array of memory cells according to some implementations of the present disclosure.

FIG. 1B illustrates a schematic block diagram of a cross-section of a semiconductor device, according to some implementations of the present disclosure.

FIG. 1C illustrates a schematic cross-sectional view of a semiconductor device, according to some implementations of the present disclosure.

FIG. 2A illustrates a schematic block diagram of a cross-section of a semiconductor device, according to some implementations of the present disclosure.

FIGS. 2B-2E illustrates schematic cross-sectional views of different semiconductor devices, according to some implementations of the present disclosure.

FIG. 3 illustrates a flowchart of a fabricating method for forming a semiconductor device, according to some implementations of the present disclosure.

FIG. 4 illustrates a flowchart of a fabricating method for forming a semiconductor device, according to some implementations of the present disclosure.

FIGS. 5A-5F each illustrates schematic views of the semiconductor device at a certain fabricating stage of the method shown in FIG. 4, according to various implementations of the present disclosure.

FIG. 6 illustrates a flowchart of a fabricating method for forming a semiconductor device, according to some implementations of the present disclosure.

FIGS. 7A-7B each illustrates schematic views of the semiconductor device at a certain fabricating stage of the method shown in FIG. 4, according to various implementations of the present disclosure.

FIG. 8 illustrates a flowchart of a fabricating method for forming a semiconductor device, according to some implementations of the present disclosure.

FIGS. 9A-9D each illustrates schematic views of the semiconductor device at a certain fabricating stage of the method shown in FIG. 4, according to various implementations of the present disclosure.

FIG. 10 illustrates a flowchart of a fabricating method for forming a semiconductor device, according to some implementations of the present disclosure.

FIGS. 11A-11B each illustrates schematic views of the semiconductor device at a certain fabricating stage of the method shown in FIG. 4, according to various implementations of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be used in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

In contemporary 3D NAND designs, specifically those employing 32-layer or higher stacks, the memory array occupies a preponderance of the die, typically accounting for 70-80% of the total chip area. Conversely, the peripheral circuit structures, encompassing control logic, address decoders, sense amplifiers, and the I/O interface, generally occupy a comparatively smaller fraction of the total die area, customarily 20-30% of the total chip area. Though the ratio can vary depending on the complexity of the NAND architecture and the specific design, the area of the peripheral circuit structure is much smaller than the area of the memory array region. Therefore, in the X-tacking structure, a significant portion of the area under the memory array is wasted.

To address one or more of the aforementioned issues, the present disclosure introduces a semiconductor device in which two memory arrays are stacked vertically, with the corresponding peripheral circuit structures located between the two memory arrays and formed on the same semiconductor structure. In the sandwich-like structure provided by the present disclosure, two peripheral circuit structures are integrated into the same semiconductor layer, rather than formed separately. Therefore, the utilization of the area under the memory array is doubled. Consistent with the scope of the present disclosure, according to some implementations of the present disclosure, the two memory arrays and the semiconductor structure on which the two corresponding peripheral circuit structures formed can be formed separately and then stacked together through hybrid bonding. In this way, the thickness of the device can be significantly reduced, down to approximately 10 μm, by retaining only the functional memory structures without needing to consider mechanical strength. Additionally, electrical components are shielded from subsequent high-temperature processes, thereby preserving their integrity and potentially improving their performance. By eliminating thermal budget considerations, the manufacturing process becomes more streamlined and flexible, which may lead to increased productivity and cost-effectiveness.

Consistent with the scope of the present disclosure, according to some implementations of the present disclosure, the disclosed semiconductor devices include vertical transistors and vertical capacitors. Each vertical transistor includes a channel layer extending in a first direction and a gate structure laterally beside the channel layer. In some implementations, a leakage value of the channel layer is lower than a pico-ampere. For example, the channel layer can include a metal oxide semiconductor material. The metal oxide semiconductors exhibit overlapping orbitals in the conduction band, which results in carrier mobility being less influenced by the ordering degree of the thin film material. Consequently, the mobility of metal oxide semiconductors ranges from approximately 1 to 100 cm²·V⁻¹·s⁻¹, which is substantially higher than that of silicon-based semiconductors. The enhanced mobility contributes to improved electrical uniformity in metal oxide semiconductors compared to silicon counterparts. Metal oxide semiconductors have low process temperature requirements, which enable compatibility with amorphous silicon (a-Si) thin film transistor (TFT) processes, facilitating fabrication on flexible plastic substrates. Furthermore, the manufacturing process for metal oxide semiconductors is potentially more cost-effective than traditional semiconductor fabrication methods. This cost reduction is achieved by eliminating the need for ion implantation and crystallization equipment, which are typically required in silicon semiconductor production.

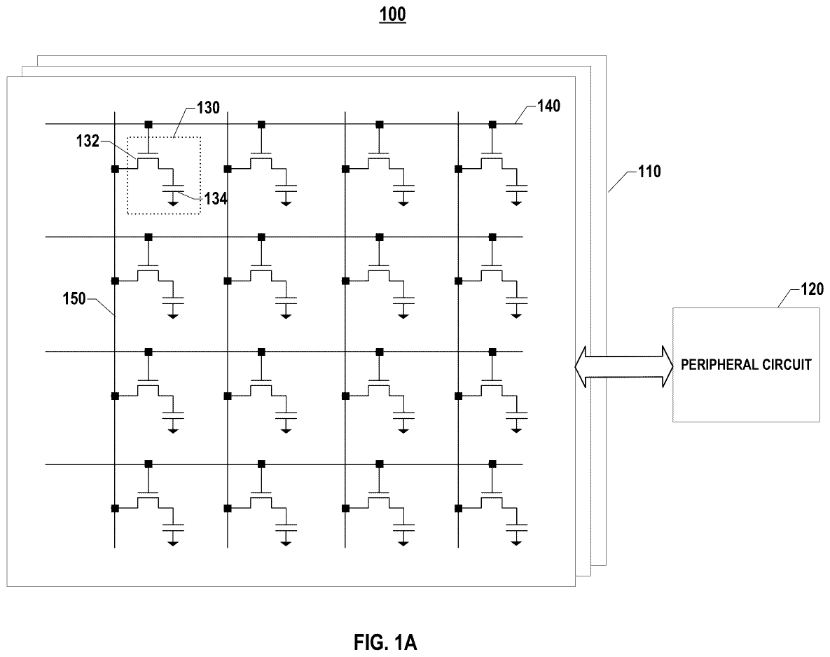

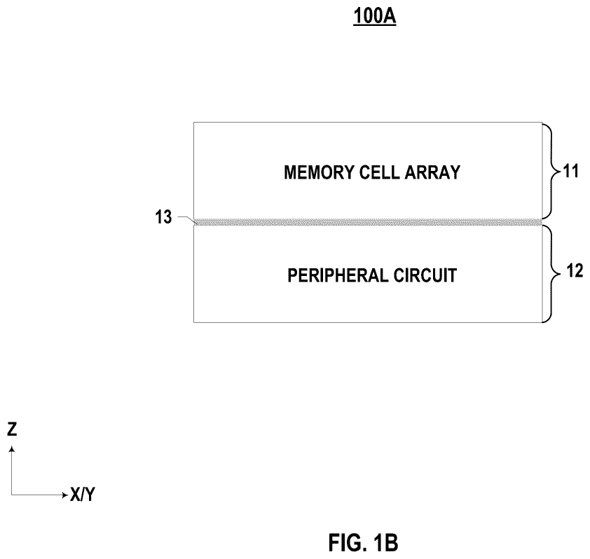

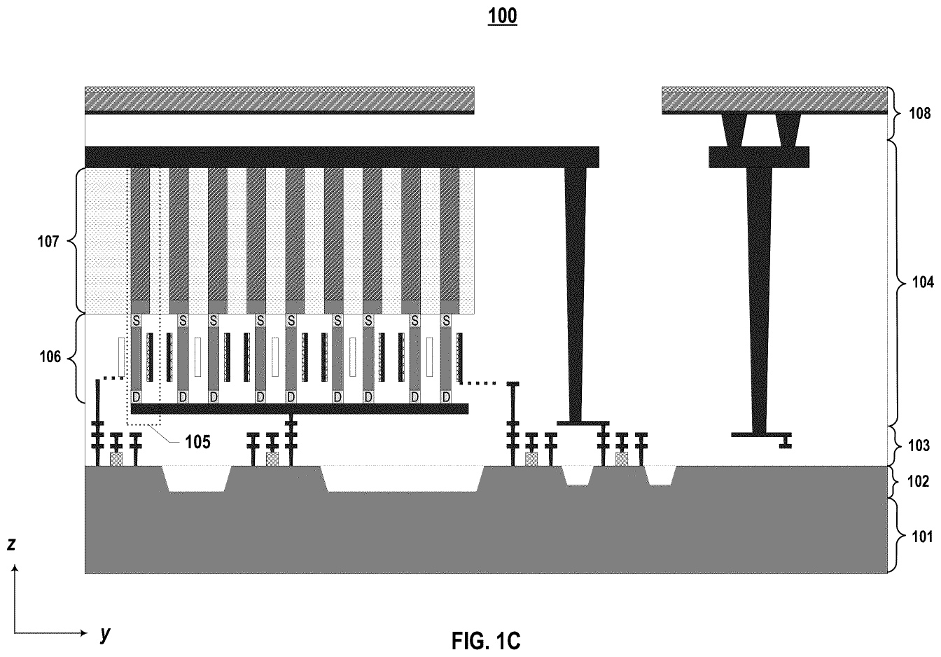

FIG. 1A illustrates a schematic diagram of a semiconductor device 100A including peripheral circuit structures and an array of memory cells each having a vertical transistor, according to some aspects of the present disclosure. Semiconductor device 100A can include a memory cell array 110 and peripheral circuit structures 120 coupled to memory cell array 110. Memory cell array 110 can be any suitable memory cell array in which each memory cell 130 includes a vertical transistor 132 and a storage unit 134 coupled to vertical transistor 132. In some implementations, memory cell array 110 is a DRAM cell array, and storage unit 134 is a capacitor for storing charge as the binary information stored by the respective DRAM cell. As shown in FIG. 1A, memory cells 130 can be arranged in a two-dimensional (2D) array having rows and columns. Peripheral circuit structures 120 can include any suitable digital, analog, and/or mixed-signal circuits used for facilitating the operations of the memory cell array. For example, the peripheral circuit structure can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuit structures 120 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations. Semiconductor device 100 can include word lines 140 coupling peripheral circuit structures 120 and memory cell array 110 for controlling the switch of vertical transistors 132 in memory cells 130 located in a row, as well as bit lines 150 coupling peripheral circuit structures 120 and memory cell array 110 for sending data to and/or receiving data from memory cells 130 located in a column. That is, each word line 140 is coupled to a respective row of memory cells 130, and each bit line 150 is coupled to a respective column of memory cells 130.

Consistent with the scope of the present disclosure, vertical transistors 132, such as vertical metal-oxide-semiconductor field-effect transistors (MOSFETs), can replace the planar transistors as the pass transistors of memory cells 130 to reduce the area occupied by the pass transistors, the coupling capacitance, as well as the interconnect routing complexity, as described below in detail. As shown in FIG. 1A, in some implementations, different from planar transistors in which the active regions are formed in the substrates, vertical transistor 132 includes a semiconductor body extending vertically (in the z-direction) above the substrate (not shown). That is, the semiconductor body can extend above the top surface of the substrate to expose not only the top surface of the semiconductor body, but also one or more side surfaces thereof. As shown in FIG. 1A, for example, the semiconductor body can have a cuboid shape to expose four sides thereof. It is understood that the semiconductor body may have any suitable shape, such as a polyhedron shape or a cylinder shape. That is, the cross-section of the semiconductor body in the plan view (e.g., in the x-y plane) can have a square shape, a rectangular shape (or a trapezoidal shape), a circular (or an oval shape), or any other suitable shapes. It is understood that consistently with the scope of the present disclosure, for semiconductor bodies that have a circular or oval shape of their cross-sections in the plan view, the semiconductor bodies may still be considered to have multiple sides, such that the gate structures are coupled with more than one side of the semiconductor bodies.

In some implementations, the semiconductor bodies can be formed from the substrate (e.g., by etching or epitaxy) and thus, have the same semiconductor material (e.g., silicon crystalline silicon) as the substrate (e.g., a silicon substrate). In some implementations, the semiconductor bodies can include metal oxide and semiconductor materials, such as low-temperature polysilicon (LTPS) and indium gallium zinc oxide. Specifically, semiconductor bodies can include one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 1A, vertical transistor 132 can also include a gate structure coupled with one or more lateral sides of semiconductor body. In other words, the active region of vertical transistor 132, i.e., the semiconductor body, can be at least partially surrounded by the gate structure. The ate structure can include a gate dielectric over one or more sides of the semiconductor body, e.g., coupled with four side surfaces of the semiconductor body as shown in FIG. 1A. The gate structure can also include a gate electrode over and coupled with gate dielectric. The gate dielectric can include any suitable dielectric materials, such as silicon oxide, silicon nitride, silicon oxynitride, or high-k dielectrics. Gate electrodes can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides.

As shown in FIG. 1A, vertical transistor 132 can further include a pair of a source and a drain (S/D, dope regions, a.k.a., source electrode and drain electrode) formed at the two ends of the semiconductor body in the first direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by the gate structure in the first direction (the z-direction). As a result, one or more channels (not shown) of vertical transistor 132 can be formed in the semiconductor body vertically between the source and drain when a gate voltage applied to the gate electrode of the gate structure is above the threshold voltage of vertical transistor 132.

In some implementations, the vertical transistors 132 can be single-gate transistors, in which the gate structure may be located at a single lateral side of the semiconductor body, for example, for the purpose of increasing the transistor and memory cell density. In some other implementations, vertical transistor 132 can be a multi-gate transistor. That is, the gate structure can be laterally located at more than one side of the semiconductor body to form more than one gate, such that more than one channel can be formed between the source and drain in operation. That is, different from the planar transistor that includes only a single planar gate (and resulting in a single planar channel), vertical transistor 132 shown in FIG. 1A can include multiple vertical gates on multiple lateral sides of the semiconductor body due to the semiconductor structure of semiconductor body and gate structure that is located on the multiple lateral sides of the semiconductor body. Compared with planar transistors, vertical transistor 132 shown in FIG. 1A can have a larger gate control area to achieve better channel control with a smaller subthreshold swing. During the off state, since the channel is fully depleted, the leakage current of vertical transistor 132 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and gate-all-around (GAA) vertical transistors.

As shown in FIG. 1A, storage unit 134 can be coupled to the source or the drain of vertical transistor 132. Storage unit 134 can include any devices that are capable of storing binary data (e.g., 0 and 1), including but not limited to, capacitors for DRAM cells and FRAM cells, and PCM elements for PCM cells. Peripheral circuit structures 120 can be coupled to memory cell array 110 through bit lines 150, word lines 140, and any other suitable metal wirings. As described above, peripheral circuit structures 120 can include any suitable circuits for facilitating the operations of memory cell array 110 by applying and sensing voltage signals and/or current signals through word lines 140 and bit lines 150 to and from each memory cell 130. Peripheral circuit structures 120 can include various types of peripheral circuit structures formed using CMOS technologies.

In some implementations, storage unit 134 can be pillar capacitors which are formed after forming the vertical transistors 132. Both the outer and inner surfaces of a pillar capacitor can be utilized as effective capacitor areas. This structure can be utilized to achieve greater packing density in a semiconductor device. In some other implementations, storage unit 134 can be cup capacitors, which are formed before forming the vertical transistors 132. In such implementations, the high-temperature processes of forming the cup capacitors do not affect the formation of vertical transistors 132. Thus, metal oxide semiconductors can be employed as the channel structures of vertical transistors 132.

FIG. 1B illustrates a side view of a cross-section of a semiconductor device 100B, according to some aspects of the present disclosure. It is understood that FIG. 1B is for illustrative purposes only and may not necessarily reflect the actual device structure (e.g., interconnections) in practice. Semiconductor device 100B can include a memory array layer 11 including multiple memory cell arrays and a peripheral circuit structure layer 12 including the peripheral circuit structures corresponding to the memory cell arrays. Semiconductor device 100A further includes an interconnection layer 13 between memory array layer 11 and peripheral circuit structure layer 12. In some implementations, semiconductor device 100B represents an example of a bonded chip. That is, the two layers of semiconductor device 100B, i.e., the memory array layer 11 and the peripheral circuit structure layer 12, can be formed separately on different substrates and then joined at a bonding interface to form a bonded chip. In some implementations, semiconductor device 100B represents an example of a single chip. That is, the two layers of semiconductor device 100B, i.e., the memory array layer 11 and the peripheral circuit structure layer 12, can be formed on the same substrate. In some implementations, a thickness of the semiconductor device 100A is less than 12 μm.

FIG. 1C illustrates a side view of a cross-section of a semiconductor device 100C, according to some aspects of the present disclosure. It is understood that FIG. 1C is for illustrative purposes only and may not necessarily reflect the actual device structure (e.g., interconnections) in practice. Semiconductor device 100C can include a substrate 101, which can include silicon (e.g., single crystalline silicon, c-Si), silicon germanium (SiGe), gallium arsenide (GaAs), germanium (Ge), silicon-on-insulator (SOI), or any other suitable materials. Semiconductor device 100C further includes peripheral circuit structures 102 formed on substrate 101. In some implementations, peripheral circuit structures 102 includes a plurality of transistors (e.g., planar transistors and/or vertical transistors). Semiconductor device 100C further includes an interconnection layer 103 above peripheral circuit structures 102 to transfer electrical signals to and from peripheral circuit structures 102. Interconnection layer 103 can include a plurality of interconnects (also referred to herein as “contacts”), including lateral interconnect lines and vertical interconnect access (VIA) contacts.

In some implementations, semiconductor device 100C includes a semiconductor layer 104 in which memory cells 105 are provided in the form of an array above interconnection layer 103. Each memory cell 105 can include a vertical transistor 106 (e.g., an example of vertical transistors 132 in FIG. 1A) and capacitor 107 (e.g., an example of storage unit 134 in FIG. 1A) coupled to the vertical transistor 106. Memory cell 105 can be a 1T1C cell consisting of one transistor and one capacitor. It is understood that memory cell 105 may be of any suitable configurations, such as 2T1C cell, 3T1C cell, etc. Vertical transistor 106 can be a MOSFET used to switch a respective memory cell 105. As shown in FIG. 1C, semiconductor device 100C can further include a pad-out interconnect layer 108 above semiconductor layer 104. Pad-out interconnect layer 108 can include interconnects formed in one or more ILD layers. Pad-out interconnect layer 108 and interconnection layer 103 can be formed on opposite sides of semiconductor layer 104. Capacitors 107 are disposed vertically between vertical transistors 106 and pad-out interconnect layer 108, according to some implementations. In some implementations, the interconnects in pad-out interconnect layer 108 can transfer electrical signals between semiconductor layer 104 and outside circuits, e.g., for pad-out purposes. As shown in FIG. 1C, memory cells and peripheral circuit structurally are segregated into distinct layers and vertically stacked. In such a stacked structure, the area occupied by peripheral circuit structures 102 is much smaller than the area occupied by memory cells 105, and a significant portion of the area on substrate 101 is wasted.

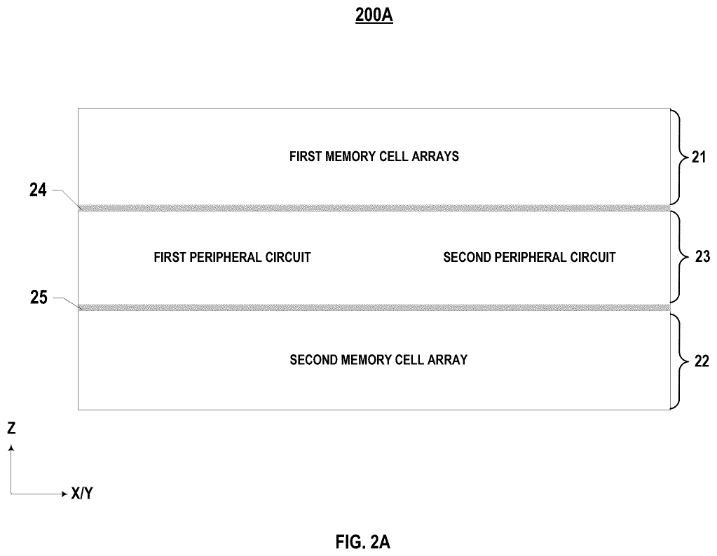

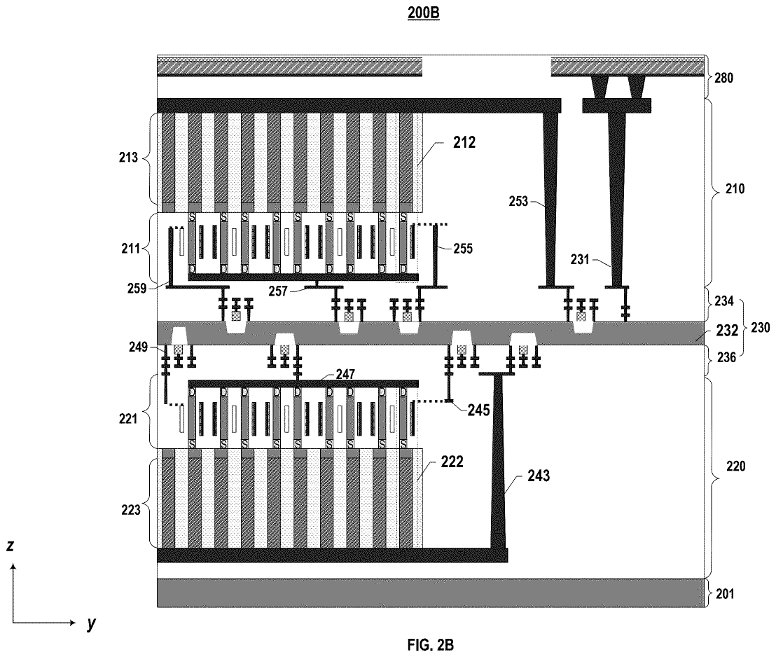

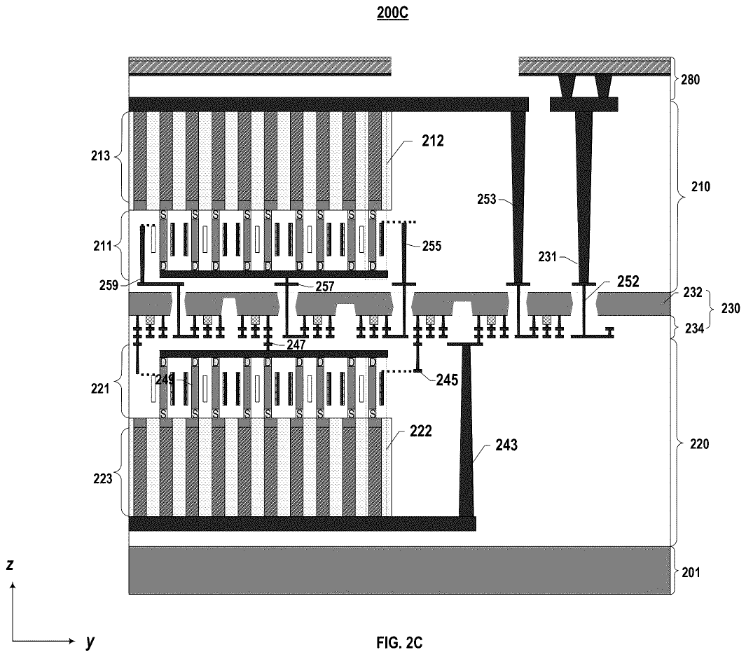

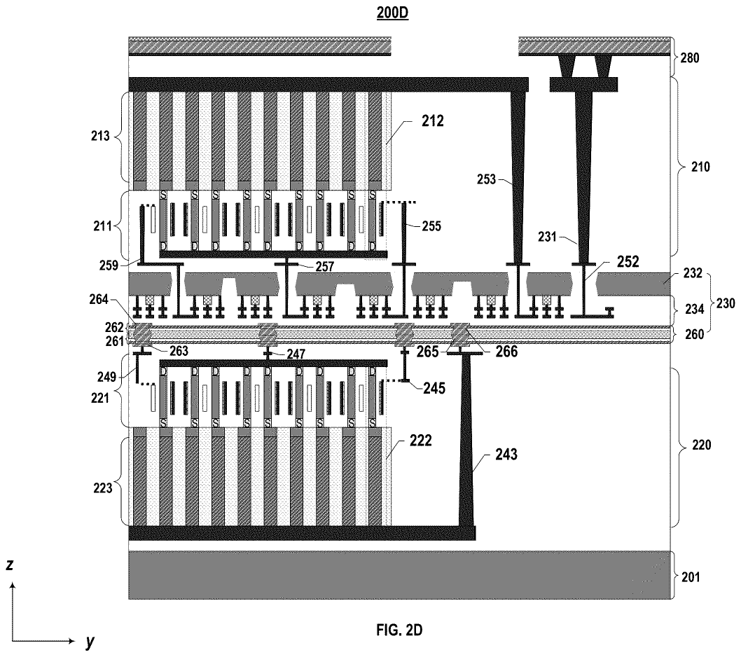

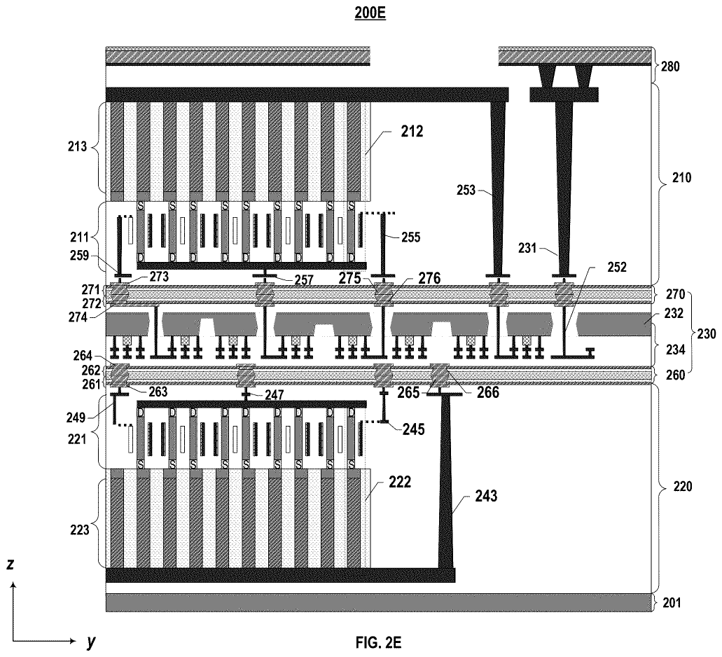

In some implementations, referring to FIG. 2A, a side view of a cross-section of a semiconductor device 200A is illustrated, according to some aspects of the present disclosure. It is understood that FIG. 2A is for illustrative purposes only and may not necessarily reflect the actual device structure (e.g., interconnections) in practice. Semiconductor device 200A can include a first semiconductor structure 21, a second semiconductor structure 22, and a third semiconductor structure 23 located between first semiconductor structure 21 and second semiconductor structure 22. First semiconductor structure 21 includes first memory cell arrays, and each first memory cell has a first transistor and a first storage unit coupled to the first transistor. Second semiconductor structure 22 includes second memory cell arrays, and each second memory cell has a second transistor and a second storage unit coupled to the second transistor. Third semiconductor structure 23 includes a first peripheral circuit structure formed on a semiconductor layer and coupled to first semiconductor structure 21 through a first interconnecting layer 24, and a second peripheral circuit structure formed on the same semiconductor layer and coupled to second semiconductor structure 22 through a second interconnecting layer 25. In some implementations, the first peripheral circuit structure and the second peripheral circuit structure are formed on the same semiconductor layer, for example, a substrate on the same wafer or a same die.

FIG. 2B illustrates a side view of a cross-section of a semiconductor device 200B, according to some aspects of the present disclosure. It is understood that FIG. 2B is for illustrative purposes only and may not necessarily reflect the actual device structure (e.g., interconnections) in practice. Semiconductor device 200B includes a first semiconductor structure 210, a second semiconductor structure 220, and a third semiconductor structure 230 located between first semiconductor structure 210 and second semiconductor structure 220.

Referring to FIG. 2B, first semiconductor structure 210, third semiconductor structure 230, and second semiconductor structure 220 are subsequently stacked on a substrate 201. First semiconductor structure 210 includes a plurality of memory cells 212 each including a vertical transistor 211 and a capacitor 213. Vertical transistor 211 can be a MOSFET used to switch a respective memory cell 212. In some implementations, vertical transistor 211 includes a channel layer (i.e., the active region in which multiple channels can form) extending vertically (in the z-direction), and a gate structure coupled with a plurality of sides of the channel layer. In some implementations, an isolation layer extending along the first direction is provided between two adjacent vertical transistors 211 to isolate the vertical transistors, as shown in FIG. 2B. In some implementations, the isolation layer may be formed by a dielectric material. In some implementations, the isolation layer may include air gaps. In some implementations, the conductive layer may further include a conductive core surrounded by dielectric material. The conductive core may connect to a common ground, thereby preventing two adjacent vertical transistors 211 from punching through.

In some implementations, the gate structure includes a gate dielectric and a gate electrode. In some implementations, the gate dielectric includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, the gate electrode includes conductive materials including, but not limited to W, Co, Cu, Al, TiN, TaN, polysilicon, silicide, or any combination thereof. In some implementations, the gate electrode includes multiple conductive layers, such as a W layer over a TiN layer. In one example, the gate structure may be a “gate oxide/gate poly” gate in which the gate dielectric includes silicon oxide and gate electrode includes doped polysilicon. In another example, the gate structure may be a high-k metal gate (HKMG) in which the gate dielectric includes a high-k dielectric, and the gate electrode includes a metal.

In some implementations, a leakage value of the channel layer is lower than a pico-ampere. For example, the channel layer can include a metal oxide semiconductor material. The orbitals in the conduction band of metal oxide semiconductor usually overlap with each other, and the carrier mobility is less affected by the ordering degree of thin film material. Thus, the mobility of metal oxide semiconductor is about 1~100 cm²·V⁻¹·s⁻¹, which is much higher than silicon. Therefore, metal oxide semiconductors have better electrical uniformity than silicon. The process temperature of metal oxide semiconductors is low and can be compatible with the a-Si thin film transistor (TFT) process, making it possible to fabricate on a flexible plastic substrate. It can also realize low-cost manufacturing since no ion implantation and crystallization equipment is needed. In a vertical structure, metal oxide semiconductors have some merits that others do not have, such as achieving short channels, reducing the device area, and suppressing mechanical stress in a flexible substrate. When the cracks are generated by compressive and tensile strain in the channel layer, the carriers could still be transported in the first direction. This structure has great potential for flexible applications. In present implementation, the semiconductor layer can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

In some implementations, semiconductor layer can be formed on a substrate by deposition processes including, but not limited to, chemical vapor deposition (CVD), physical vapor deposition (PVD), atomic layer deposition (ALD), or any combination thereof. Therefore, the semiconductor layer may be a thin film with a thickness much smaller than its width. For example, the of the channel layer in the y-direction is smaller than a width of the semiconductor layer in the x-direction. In some implementations, a ratio between the width and the thickness of the semiconductor layer ranges from 10 to 500. For example, the thickness of the semiconductor layer may be 5 nm while the width of the semiconductor layer may be 200 nm, i.e., ratio between the width and the thickness of the semiconductor layer is 40. The thickness of the semiconductor layer may be 14 nm while the width of the semiconductor layer may be 280 nm, i.e., the ratio between the width and the thickness of the semiconductor layer is 20. The thickness of the semiconductor layer may be 2 nm while the width of the semiconductor layer may be 300 nm, i.e., the ratio between the width and the thickness of the semiconductor layer may be 150. It should be noted that the dimension of the thickness and width and the ratio between them described in the present disclosure is illustrative and should not be considered as a limitation of the present disclosure.

In some implementations, the channel layer has two ends (the upper end and lower end) in the first direction (the z-direction), and both ends extend beyond the gate structure, respectively, in the first direction. That is, the channel layer can have a larger vertical dimension (e.g., the depth) than that of the gate structure (e.g., in the z-direction), and neither the upper end nor the lower end of the channel layer is flush with the respective end of the gate structure. In some implementations, the channel layer includes a first portion extending along the first direction, and a second portion extending from an end of the vertical portion towards an adjacent vertical transistor along a second direction (i.e., the y-direction). The vertical portion of the channel layer can be used as the channel of vertical transistor 211. The gate dielectric of the gate structure is coupled with the vertical portion of the channel layer, and the gate electrode is coupled with the gate dielectric. The second portion of the channel layer is coupled with a source node contact.

Referring to FIG. 2B, second semiconductor structure 220 includes a plurality of memory cells 222 each including a vertical transistor 221 and a capacitor 223. The structure of second semiconductor structure 220 may be the same as first semiconductor structure 210, and the details of second semiconductor structure will not be repeated herein. It should be noted that the arrangement of first semiconductor structure 210 and second semiconductor structure 220 can be designed based on the corresponding fabrication processes. For example, in fabrication processes in which the capacitors of each memory cell are designed to form before corresponding vertical transistors, first capacitor 213 can be located between first vertical transistor 211 and third semiconductor structure 230 along the first direction, and second capacitor 223 can be located between second vertical transistor 221 and third semiconductor structure 230 along the first direction. In fabrication processes in which the capacitors of each memory cell are designed to form after corresponding vertical transistors, first vertical transistor 211 can be located between first capacitor 213 and third semiconductor structure 230 along the first direction, and second vertical transistor 221 can be located between second capacitor 223 and third semiconductor structure 230 along the first direction. In fabrication processes in which first semiconductor structure 210 and second semiconductor structure 220 are formed separately and independently, first vertical transistor 211 may be located between first capacitor 213 and third semiconductor structure 230 along the first direction, and second capacitor 223 may be located between second vertical transistor 221 and third semiconductor structure 230 along the first direction.

In some implementations, third semiconductor structure 230 includes a semiconductor layer 232 on which the first peripheral circuit structure and the second peripheral circuit structure is formed. Referring to FIG. 2B, in some implementations, the first peripheral circuit structure is formed on a first side of semiconductor layer 232 and is coupled with first semiconductor structure 210 through a first interconnecting layer 234. The second peripheral circuit structure is formed on a second side of semiconductor layer 232 and is coupled with second semiconductor structure 220 through a second interconnecting layer 236. The second side of the semiconductor layer is opposite to the first side of the semiconductor layer.

In some implementations, first interconnecting layer 234 and second interconnecting layer 236 can include a plurality of contacts, including lateral interconnect lines and vertical interconnect access (VIA) contacts. As used herein, the term “contacts” can broadly include any suitable types of interconnects, such as middle-end-of-line (MEOL) interconnects and back-end-of-line (BEOL) interconnects. first interconnecting layer 234 and second interconnecting layer 236 can further include one or more interlayer dielectric (ILD) layers (also known as “intermetal dielectric (IMD) layers”) in which the interconnect lines and via contacts can form. That is, first interconnecting layer 234 and second interconnecting layer 236 can include interconnect lines and via contacts in multiple ILD layers. In some implementations, the first peripheral circuit structure may be coupled to second peripheral circuit structure through the interconnects in first interconnecting layer 234 and second interconnecting layer 236. The interconnects can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, first semiconductor structure 210 further comprises a plurality of first contacts coupled between first interconnecting layer 234 and the first memory cells. In some implementations, the first contacts include a first word line contacts 255 configured to couple the word lines of first memory arrays with first interconnecting layer 234. The first contacts may include a first bit word line contacts 257 configured to couple the bit lines of first memory arrays with first interconnecting layer 234. The first contacts may include a first capacitor contacts 253 configured to couple a common electrode of first capacitors 213 in a memory array with first interconnecting layer 234. In some implementations, the first contacts may further include a shielding contact 259 configured to couple the conductive core between two adjacent first vertical transistors 211 to a common ground.

In some implementations, second semiconductor structure 220 further comprises a plurality of second contacts coupled between the second interconnecting layer 236 and second memory cells. In some implementations, the second contacts include a second word line contacts 245 configured to couple the word lines of second memory arrays with second interconnecting layer 236. The second contacts may include a second bit word line contacts 247 configured to couple the bit lines of second memory arrays with second interconnecting layer 236. The second contacts may include a second capacitor contact 243 configured to couple a common electrode of second capacitors 223 in a memory array with second interconnecting layer 236. In some implementations, the second contacts may further include a second shielding contact 249 configured to couple the conductive core between two adjacent second vertical transistors 221 to a common ground. In some implementations, the plurality of first contacts and the plurality of second contacts are misaligned along the first direction, i.e., the z-direction.

As shown in FIG. 2B, semiconductor device 200B can further include a pad-out interconnect layer 280 including interconnects formed in one or more ILD layers. Pad-out interconnect layer 280 can be formed on a top of first semiconductor structure 210 or a top of second semiconductor structure 220. In some implementations, first semiconductor structure 210 includes pad-out contacts 231 coupled between pad-out interconnect layer 108 and first interconnecting layer 234 or second interconnecting layer 236. Pad-out contacts 231 may be misaligned with the second contacts formed in second semiconductor structure 220. In some implementations, the interconnects in pad-out interconnect layer 280 can transfer electrical signals between semiconductor device 200B and outside circuits, e.g., for pad-out purposes. In some implementations, pad-out interconnect layer 280 further includes one or more contacts and vias surrounded by a dielectric spacer (e.g., having silicon oxide) to electrically separate the contacts and vias. Contacts can be an interlayer via (ILV) having a depth in the submicron-level (e.g., between 10 nm and 1 μm), or a through substrate via (TSV) having a depth in the micron-or tens micron-level (e.g., between 1 μm and 100 μm).

Referring to FIG. 2C, a semiconductor device 200C is provided according to some implementations of the present disclosure. Semiconductor device 200C includes first semiconductor structure 210 and second semiconductor structure 220, which may be the same as discussed in semiconductor device 200B with reference to FIG. 2B, which will not be discussed herein to avoid redundancy. Semiconductor device 200C is distinguished from semiconductor device 200B in the structure of the third semiconductor structure 230. As illustrated in FIG. 2C, in semiconductor device 200C, both the first peripheral circuit structure and the second peripheral circuit structure are located on the same side of semiconductor layer 232 and oriented towards second semiconductor structure 220. As previously mentioned, the area occupied by a peripheral circuit structure is smaller than that of the corresponding memory array, which allows for the formation of both the first and second peripheral circuit structures on the same side of semiconductor layer 232. In this implementation, both the first and second peripheral circuit structures can be fabricated using the same processes, and the first interconnecting layer 234 is formed over and connected to both the first and second peripheral circuit structures. This approach significantly reduces fabrication costs compared to semiconductor device 200B.

Referring to FIG. 2C, the first peripheral circuit structure and the second peripheral circuit structure are isolated from each other by interlayer dielectrics formed between them on semiconductor layer 232, and first interconnecting layer 234 is coupled with the first peripheral circuit structure and the second peripheral circuit structure separately. The second semiconductor structure 220 can be directly coupled to the second peripheral circuit structure through the first interconnecting layer 234. Meanwhile, the first semiconductor structure 210 is connected to the first peripheral circuit structure via a plurality of vias 252 that extend through semiconductor layer 232. These vias 252 are created throughout semiconductor layer 232 to establish the connection between the first semiconductor structure 210 and the first interconnecting layer 234. The thickness of semiconductor layer 232 ranges from 50 nm to 1000 nm. In some implementations, the thickness of semiconductor layer 232 may be reduced to facilitate the formation of the plurality of vias 252.

FIG. 2D provides a semiconductor device 200D according to some implementations of the present disclosure. Semiconductor device 200D also includes first semiconductor structure 210 and second semiconductor structure 220, which may be the same as discussed in semiconductor devices 200B and 200C with reference to FIGS. 2B and 2C. Similar components will not be discussed herein to avoid redundancy. Semiconductor device 200D distinguishes from semiconductor device 200C in the coupling approach between second semiconductor structure 220 and third semiconductor structure 230.

As illustrated in FIG. 2D, in semiconductor device 200D, both the first peripheral circuit structure and the second peripheral circuit structure are located on the same side of semiconductor layer 232 and oriented towards second semiconductor structure 220, as illustrated in FIG. 2C. Unlike in semiconductor devices 200B and 200C, the three semiconductor structures are formed subsequently upon one another. In this implementation, second semiconductor structure 220 is formed separately from third semiconductor structure 230. In some implementations, third semiconductor structure 230 and second semiconductor structure 220 can be bonded together at the bonding interface 260 to form semiconductor device 200D. Bonding interface 260 can be an interface between third semiconductor structure 230 and second semiconductor structure 220 formed by any suitable bonding technologies, such as hybrid bonding, anodic bonding, fusion bonding, transfer bonding, adhesive bonding, and eutectic bonding, to name a few.

Referring to FIG. 2D, a first bonding structure 261 and a second bonding structure 262 are illustrated, according to some implementations of the present disclosure. In some implementations, first bonding structure 261 includes at least one dielectric layer covering a bonding surface of second semiconductor structure 220, a first bonding contacts 265 extending though the dielectric layer, and a first conductive pad 263 coupled between the first bonding contacts 265 and second semiconductor structure 220. Second bonding structure 262 includes at least one dielectric layer covering a bonding surface of third semiconductor structure 230, a second bonding contacts 266 extending though the dielectric layer, and a second conductive pad 264 coupled between the second bonding contacts 266 and third semiconductor structure 230. In some implementations, first bonding structure 261 may include a first carbon nitride layer where the first conductive pad 263 is embedded, and second bonding structure 262 may include a second carbon nitride layer where the second conductive pad 264 is embedded. In some implementations, first bonding structure 261 includes a first silicon oxide layer where the first conductive pad 263 is embedded, and the second bonding structure 262 may include a second silicon oxide layer where the second conductive pad 264 is embedded. In some implementations, first bonding contacts 265 are in contact with the second bonding contacts 266 at the bonding interface 260 after the bonding.

FIG. 2E provides a semiconductor device 200E according to some implementations of the present disclosure. Semiconductor device 200E also includes first semiconductor structure 210 and second semiconductor structure 220, which may be the same as discussed in semiconductor devices 200B, 200C, and 200D with reference to FIGS. 2B-2D. Similar components will not be discussed herein to avoid redundancy. Semiconductor device 200E distinguishes from semiconductor device 200D in the coupling approach between first semiconductor structure 210 and third semiconductor structure 230.

As illustrated in FIG. 2E, in semiconductor device 200E, both the first peripheral circuit structure and the second peripheral circuit structure are located on the same side of semiconductor layer 232 and oriented towards second semiconductor structure 220, as illustrated in FIG. 2C. Unlike semiconductor device 200D, not only second semiconductor structure 220 is coupled to third semiconductor structure 230 through a bonding structure, first semiconductor structure 210 is also formed separately from third semiconductor structure 230 and coupled to third semiconductor structure 230 through a bonding structure. In some implementations, first semiconductor structure 210, second semiconductor structure 220, and third semiconductor structure 230 can be fabricated separately, and bonded together through a bonding process. In this way, thermal distribution generated in subsequent fabrication processes can be significantly reduced.

In some implementations, third semiconductor structure 230 and first semiconductor structure 210 can be bonded together at the bonding interface 270, third semiconductor structure 230 and second semiconductor structure 220 can be bonded together at the bonding interface 260. Bonding interfaces 260 and 270 can be formed by any suitable bonding technologies, such as hybrid bonding, anodic bonding, fusion bonding, transfer bonding, adhesive bonding, eutectic bonding, to name a few.

Referring to FIG. 2E, a third bonding structure 271 and a fourth bonding structure 272 are illustrated, according to some implementations of the present disclosure. In some implementations, third bonding structure 271 includes at least one dielectric layer covering a bonding surface of first semiconductor structure 210, a third bonding contacts 275 extending though the dielectric layer, and a third conductive pad 273 coupled between the third bonding contacts 275 and first semiconductor structure 210. Fourth bonding structure 272 includes at least one dielectric layer covering a bonding surface of third semiconductor structure 230, a fourth bonding contacts 276 extending though the dielectric layer, and a fourth conductive pad 274 coupled between the fourth bonding contacts 276 and first semiconductor structure 210. In some implementations, third bonding structure 271 may include a third carbon nitride layer where the third conductive pad 273 is embedded, and fourth bonding structure 272 may include a fourth carbon nitride layer where the fourth conductive pad 274 is embedded. In some implementations, third bonding structure 271 includes a third silicon oxide layer where the third conductive pad 273 is embedded, and the fourth bonding structure 272 may include a fourth silicon oxide layer where the fourth conductive pad 274 is embedded. In some implementations, third bonding contacts 275 are in contact with the fourth bonding contacts 276 at the bonding interface 270 after the bonding.

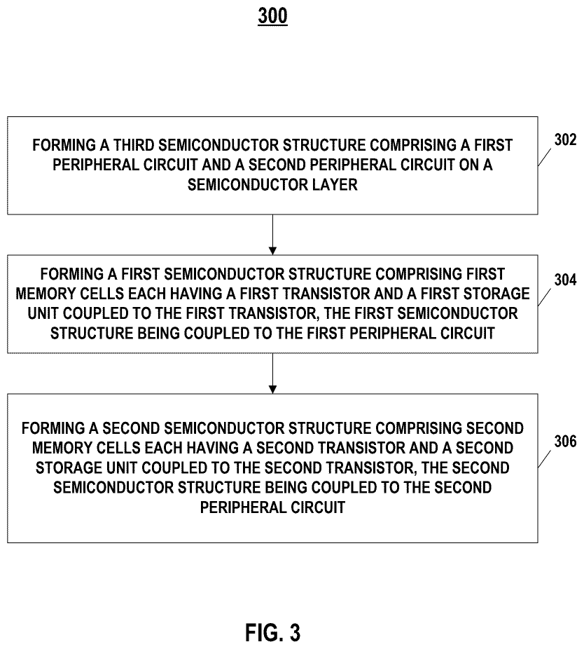

FIG. 3 illustrates a flowchart of a fabricating method 300 for forming a semiconductor structure, according to some implementations of the present disclosure. It is understood that the operations shown in method 300 are not exhaustive and that other operations can be performed as well before, after, or between any of the illustrated operations. Further, some of the operations may be performed simultaneously, or in a different order than shown in FIG. 3.

As shown in FIG. 3, method 300 can start at operation 302, in which a third semiconductor structure includes a first peripheral circuit structure and a second peripheral circuit structure on a semiconductor layer. The semiconductor layer may be a semiconductor substrate including a wide array of semiconductor materials, such as silicon, germanium, gallium arsenide, indium phosphide, etc. Alternatively, the substrate can be made from an electrically non-conductive material, such as a glass, a plastic, or a sapphire wafer. In some implementations, the first peripheral circuit structure and the second peripheral circuit structure are formed on two opposite sides of the semiconductor layer respectively. In some implementations, the first peripheral circuit structure and the second peripheral circuit structure are formed on a same side of the semiconductor layer.

As shown in FIG. 3, method 300 can start at operations 304 and 306, in which a first semiconductor structure and a second semiconductor structure are formed on two opposite sides of the third semiconductor structure. The first semiconductor includes first memory cells each having a first transistor and a first storage unit coupled to the first transistor, the first semiconductor structure is coupled to the first peripheral circuit structure on a first side of the third semiconductor structure. The second semiconductor includes second memory cells each having a second transistor and a second storage unit coupled to the second transistor, the second semiconductor structure is coupled to the second peripheral circuit structure on a second side of the third semiconductor structure; the second side is opposite to the first side of the third semiconductor structure. It should be noted that the sequence for forming the first semiconductor structure, the second semiconductor structure, and the third semiconductor structure can be adjusted to align with various fabrication processes. In some implementations, the third semiconductor structure may be formed first on a substrate, followed by the formation of the first semiconductor structure above it. Subsequently, the second semiconductor structure may be formed on the backside of the substrate after the substrate has been thinned. In some implementations, at least one of the first and second semiconductor structures may be formed on a separate substrate and subsequently bonded to the third semiconductor structure. The formation sequence of the semiconductor structures described in the present disclosure is illustrative and should not be considered as a limitation of the present disclosure.

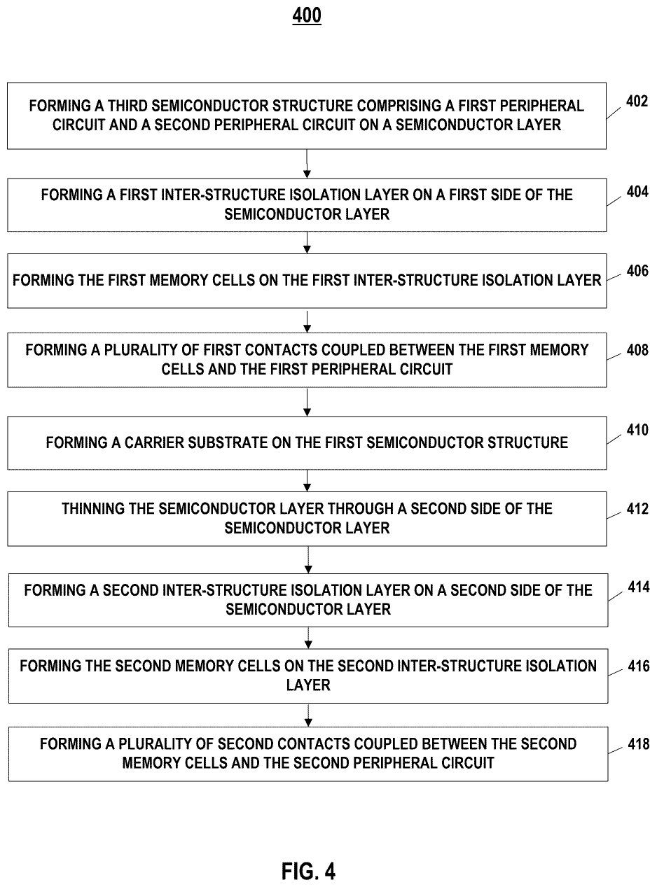

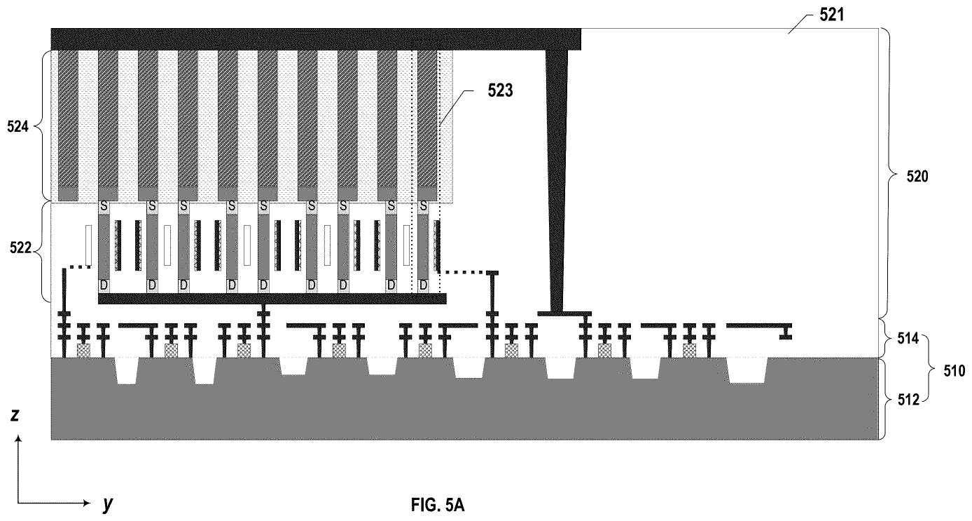

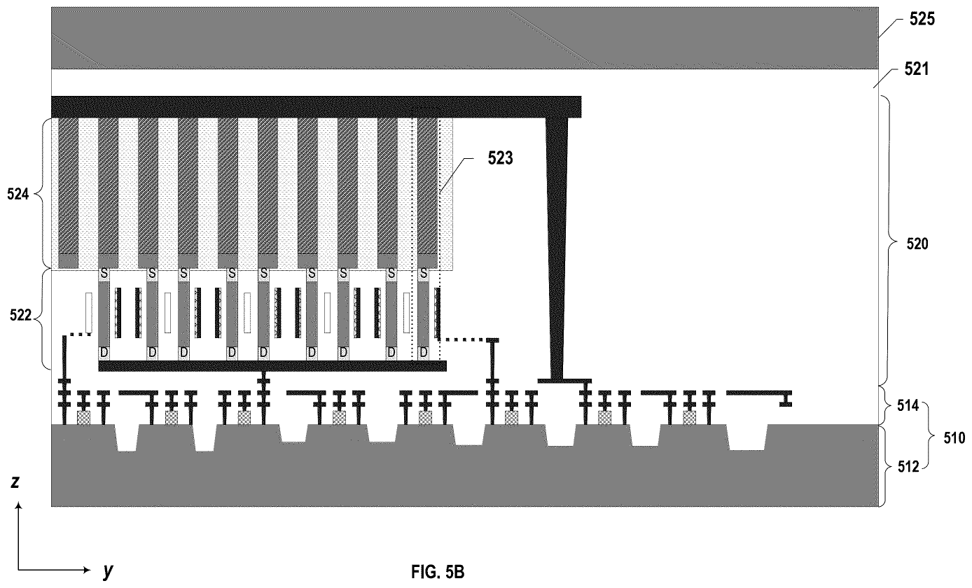

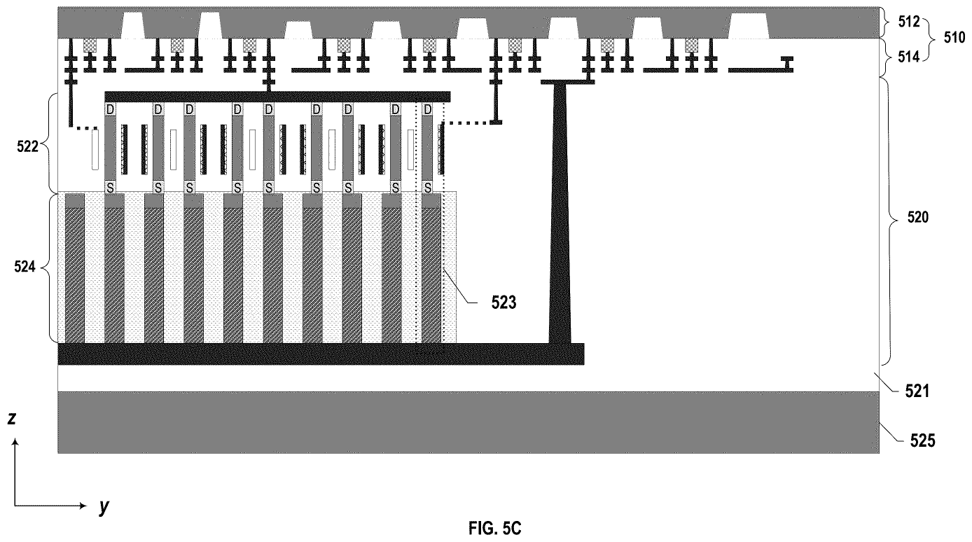

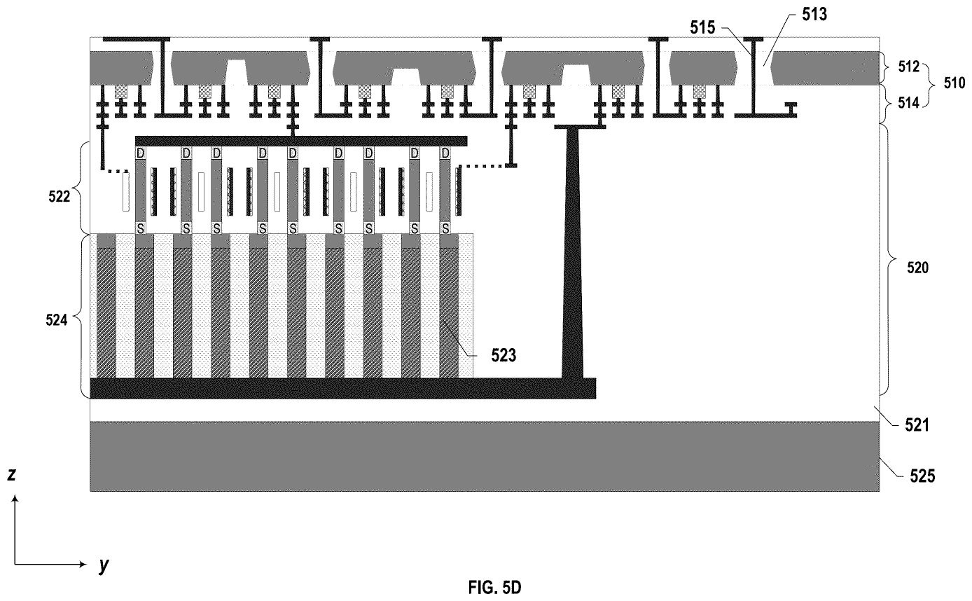

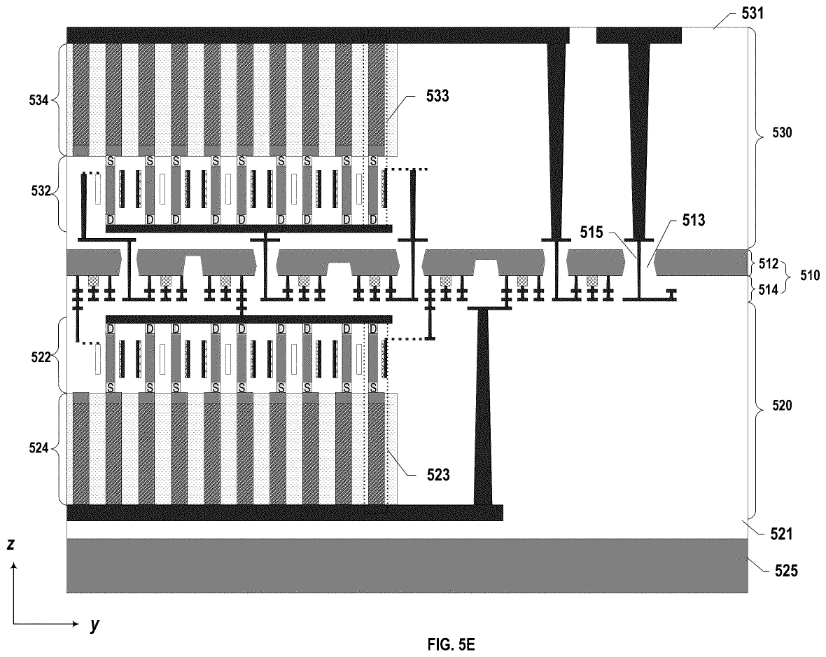

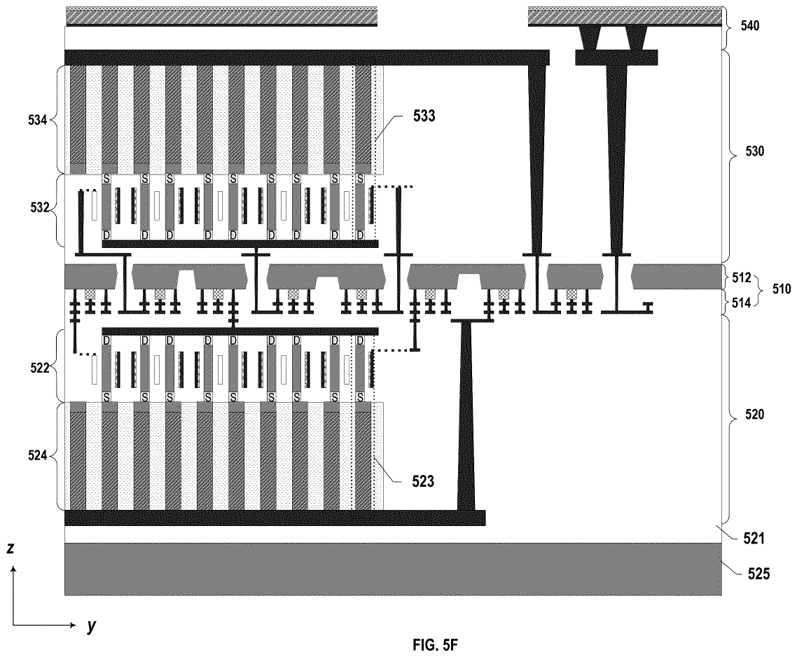

FIG. 4 illustrates a flowchart of a fabricating method 400 for forming a semiconductor structure, according to some implementations of the present disclosure. FIGS. 5A-5F illustrate schematic views of a semiconductor device at certain fabricating stages of the method 400 shown in FIG. 4, according to various implementations of the present disclosure. It is understood that the operations shown in method 400 are not exhaustive and that other operations can be performed as well before, after, or between any of the illustrated operations. Further, some of the operations may be performed simultaneously, or in a different order than shown in FIG. 4.

As shown in FIGS. 4 and 5A, method 400 can start at operation 402, in which a third semiconductor structure 510 including a first peripheral circuit structure and a second peripheral circuit structure on a substrate 512. Substrate 512 may be a semiconductor substrate including a wide array of semiconductor materials, such as silicon, germanium, gallium arsenide, indium phosphide, etc. Alternatively, substrate 512 can be made from an electrically non-conductive material, such as a glass, a plastic, or a sapphire wafer. In some implementations, as shown in FIG. 5A, the first peripheral circuit structure and the second peripheral circuit structure are formed on the same side of the substrate 512. In some implementations, the first peripheral circuit structure and the second peripheral circuit structure are formed on two opposite sides of the semiconductor layer respectively.

In some implementations, a first interconnecting layer 514 is formed on and coupled with the first peripheral circuit structure and the second peripheral circuit structure respectively. First interconnecting layer 514 can include a plurality of contacts, including lateral interconnect lines and vertical interconnect access (VIA) contacts. As used herein, the term “contacts” can broadly include any suitable types of interconnects, such as MEOL interconnects and BEOL interconnects. First interconnecting layer 514 can further include one or more ILD in which the interconnect lines and via contacts can form. That is, first interconnecting layer 514 can include interconnect lines and via contacts in multiple ILD layers. In some implementations, the first peripheral circuit structure may be coupled to second peripheral circuit structure through the interconnects in first interconnecting layer 514. The interconnects can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

Referring back to FIG. 4 and FIG. 5A, method 400 proceeds to operation 404, in which a first inter-structure isolation layer 521 is formed on a first side of the semiconductor layer, i.e., first inter-structure isolation layer 521 is formed covering first interconnecting layer 514. First inter-structure isolation layer 521 can include dielectric materials deposited by one or more thin film deposition processes including, but not limited to, CVD, PVD, ILD, and similar techniques or any combination thereof.

Method 400 proceeds to operation 406, in which a plurality of first memory cells 523 are formed in first inter-structure isolation layer 521 and coupled with first interconnecting layer 514. In some implementations, each first memory cell 523 includes a vertical transistor 522 and a capacitor 524 coupled with corresponding vertical transistor 522. In some implementations, an array of capacitors 524 is formed first and followed by the fabrication of vertical transistors 522. In some implementations, capacitors 524 are formed after the fabrication of vertical transistors 522. The sequence of the formation of vertical transistor 522 and capacitors 524 can be arranged to align with practical fabrication processes.

In some implementations, each capacitor 524 can include a first electrode coupled to a common plate, a plurality of second electrodes, and a capacitor dielectric between the first electrode and second electrodes. In some implementations, first electrodes and/or the second electrodes can include conductive materials including, but not limited to, W, Co, Cu, Al, TiN, TaN, polysilicon, silicide, or any combination thereof. In some implementations, the capacitor dielectric includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, the array of capacitors 524 can be formed by a series of fabricating processes including thin film deposition processes (e.g., CVD, PVD, ILD, etc.) and patterning processes (e.g., photoetching, dry etching, wet etching, cleaning, chemical mechanical polishing (CMP), etc. It is noted that, the fabricating processes and/or orders of forming first electrodes, second electrodes, and the capacitor dielectric can be varied depending on a front-side process or a back-side process.

In some implementations, vertical transistor 522 may be an example of a single-gate vertical transistor. Gate structure can be coupled with one side of a channel layer (the active region in which channels are formed) extending vertically. In some implementations, the channel layer has two ends (the upper end and lower end) in the first direction (the z-direction). The lower end of the channel layer covers a top surface of a corresponding capacitor 524. A vertical portion of the channel layer can be used as the channel of vertical transistor 522. In some implementations, the channel layer can be formed from a deposition process. In some implementations, the channel layer can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

In some implementations, the channel layers of vertical transistors 522 can be formed on a substrate through thin film deposition processes such as CVD, PVD, ILD, and similar techniques. The substrates may include a plurality of vertically extended semiconductor bodies and the channel layers will be formed on the vertically extended surfaces of the semiconductor bodies. The semiconductor body may include silicon (e.g., single crystalline silicon, c-Si), silicon germanium (SiGe), gallium arsenide (GaAs), germanium (Ge), silicon-on-insulator (SOI), or any other suitable materials. The channel layer has a different material with the semiconductor body and a leakage value of the channel layer is lower than a pico-ampere. A thickness of the channel layers is considerably smaller than that of the semiconductor body because they are formed in a separate deposition process. This reduced thickness of the channel layer can significantly lower the cutoff current of vertical transistor 522.

In some implementations, the channel layer may be a thin film with a thickness much smaller than its width. For example, the of the channel layer in the y-direction is smaller than a width of the channel layer in the x-direction. In some implementations, a ratio between the width and the thickness of the channel layer ranges from 10 to 500. For example, the thickness of the channel layer may be 5 nm while the width of the channel layer may be 200 nm, i.e., ratio between the width and the thickness of the channel layer is 40. The thickness of the channel layer may be 14 nm while the width of the channel layer may be 280 nm, i.e., the ratio between the width and the thickness of the channel layer is 20. The thickness of the channel layer may be 2 nm while the width of the channel layer may be 300 nm, i.e., the ratio between the width and the thickness of the channel layer may be 150. It should be noted that the dimension of the thickness and width and the ratio between them described in the present disclosure is illustrative and should not be considered as a limitation of the present disclosure.

In some implementations, a semiconductor layer, such as an InxGayZnzO layer, is deposited to cover the vertically extending surfaces of the substrates as well as the surfaces between adjacent substrates. This semiconductor layer is then truncated to create a plurality of isolated channel layers corresponding to each of vertical transistors 522. In some implementations, vertical transistors 522 include mirror single-gate transistors (MSG). In an array of MSG transistors, the channel layers of two adjacent transistors are symmetrically arranged and is face-to-face with each other. In the fabrication processes of the MSG transistors array, the semiconductor layer must be cut off from the bottom of the semiconductor body for isolation. In some implementations, the semiconductor layer that covers the surfaces between two adjacent substrates may not be entirely removed to obtain a longer channel length. In such cases, an “L-shaped” channel layer can be formed. For example, each channel layer includes a vertical portion extending along the first direction (i.e., the z-direction), and an extending portion extending from an end of vertical portion towards an adjacent vertical transistor along a second lateral direction (i.e., the y-direction). The extending portion is coupled with the capacitor. The channel layer may have an L-shaped cross-section on the y-z plane. With the extending portion, the length of the channel layer is extended, and the contact area between the source of the vertical transistor and the capacitor is expanded as well.

A gate dielectric layer can be formed to cover the channel layer and the extending portion of the channel layer. The gate dielectric layer can include any suitable dielectric materials, such as silicon oxide, silicon nitride, silicon oxynitride, or high-k dielectrics. A gate electrode can be formed to cover the gate dielectric layer. The ate electrode can include any suitable conductive materials, such as polysilicon, metals (e.g., W, Cu, Al, etc.), metal compounds (e.g., TiN, TaN, etc.), or silicide. For example, the gate electrode may include doped polysilicon, i.e., a gate poly. In some implementations, the gate electrode includes multiple conductive layers, such as a W layer over a TiN layer.

In some implementations, at least one end of the vertical portion of the channel layer extends beyond the gate dielectric layer in the first direction (the z-direction). In some implementations, one end of the vertical portion of the channel layer is flush with the respective end of the gate dielectric layer. In some implementations, both ends of the channel layer extend beyond the gate electrode, respectively, in the first direction (the z-direction). That is, the channel layer can have a larger vertical dimension (e.g., the depth) than that of the gate electrode. Vertical transistor 522 can further include a source and a drain disposed at the two ends of the channel layer, respectively, in the first direction. In some implementations, one of the source and drain is coupled to capacitor 524, and the other one of the source and drain is coupled to a bit line.

Referring back to FIG. 4 and FIG. 5A, method 400 proceeds to operation 408, in which a plurality of first contacts coupled between the first memory cells and the first peripheral circuit structure. FIG. 5B is a schematic side cross-sectional view of the semiconductor structures in the y-z plane after operation 408 of method 400.

In some implementations, the first contacts include a first word line contacts configured to couple the word lines of first memory arrays with the first interconnecting layer. The first contacts may include a first bit word line contacts configured to couple the bit lines of first memory arrays with the first interconnecting layer. The first contacts may include a first capacitor contacts configured to couple a common electrode of first capacitors in a memory array with the first interconnecting layer. In some implementations, the first contacts may further include a shielding contact configured to couple the conductive core between two adjacent first vertical transistors to a common ground.

Referring back to FIG. 4 and FIG. 5B, method 400 proceeds to operation 410, in which a carrier substrate 525 is formed on first semiconductor structure 520. FIG. 5B is a schematic side cross-sectional view of the semiconductor structures in the y-z plane after operation 408 of method 400.

In some implementations, carrier substrate 525 provides mechanical support and stability during subsequent fabrication as the second semiconductor structure will be formed on the backside of third semiconductor structure 510. Substrate 512 will be thinned and carrier substrate 525 is to provide support when substrate 512 has become very thin or if it's a brittle material or when third semiconductor structure 510 is bonded to another semiconductor structure. In some implementations, carrier substrate 525 may be used temporarily and may be removed or separated at the end of the fabrication process. Carrier substrate 525 does not contain active components or transistors like a device wafer; its main purpose is physical support. In some implementations, carrier substrate 525 may be made of silicon, glass, ceramic, or metal. The material choice depends on the specific process requirements and the properties needed (e.g., thermal conductivity, mechanical strength).

Referring to FIG. 4 and FIG. 5C, method 400 proceeds to operation 412, in which substrate 512 is thinned through the backside of substrate 512. FIG. 5C is a schematic side cross-sectional view of the semiconductor structures in the y-z plane after operation 412 of method 400.

In some implementations, after carrier substrate 525 is formed on the first semiconductor structure 520, rotating diamond abrasives or other abrasive materials will be used by a grinding machine to remove material from the backside of substrate 512. The thickness of substrate 512 may be reduced to an approximate level after back grinding. After the grinding process, chemical etching is employed to remove grinding-induced damage or imperfections on the surface of substrate 512. A chemical etchant (usually a solution of acids or bases) is used to smooth the wafer and improve its surface finish. In some implementations, polishing (specifically Chemical-Mechanical Polishing, or CMP) is used to achieve a smooth and defect-free surface after grinding. The wafer is polished using a slurry, which contains fine abrasive particles and a chemical solution that aids in smoothing out the wafer surface.

Referring to FIG. 5D, a plurality of through holes 513 are formed throughout substrate 512 so that a plurality of vias 515 can be formed to couple with the second peripheral circuit structure. In some implementations, second semiconductor structure 530 can be directly coupled to the second peripheral circuit structure through the first interconnecting layer 514, which is formed on the backside of second semiconductor structure 530. That is, second semiconductor structure 530 is connected to the second peripheral circuit structure via a plurality of vias 515 that extend through substrate 512. These vias 515 are created throughout substrate 512 to establish the connection between the first semiconductor structure 520 and the first interconnecting layer 514.

Referring to FIG. 4 and FIG. 5E, method 400 proceeds to operation 414, in which a second inter-structure isolation layer 531 is formed on the backside of substrate 512. Second inter-structure isolation layer 531 can include dielectric materials deposited by one or more thin film deposition processes including, but not limited to, CVD, PVD, ILD, or any combination thereof.

Method 400 proceeds to operation 416, in which a plurality of second memory cells 533 are formed in second inter-structure isolation layer 531 and coupled with first interconnecting layer 514 through the plurality of vias 515. In some implementations, each second memory cell 533 includes a vertical transistor 532 and a capacitor 534 coupled with corresponding vertical transistor 532. In some implementations, an array of capacitors 534 is formed first and followed by the fabrication of vertical transistors 532. In some implementations, capacitors 534 is formed after the fabrication of vertical transistors 532. The sequence of the formation of vertical transistor 532 and capacitors 534 can be arranged to align with practical fabrication processes. The detailed structure and fabrication processes for forming second memory cells 533 may be the same as first memory cells 523 and will not be repeated here.

Referring to FIG. 4 and FIG. 5E, method 400 proceeds to operation 418, in which a plurality of second contacts coupled between the second memory cells 533 and the first peripheral circuit structure. FIG. 5E is a schematic side cross-sectional view of the semiconductor structures in the y-z plane after operation 418 of method 400. In some implementations, the second contacts include a second word line contacts configured to couple the word lines of second memory arrays with first interconnecting layer 514. The second contacts may include second bit word line contacts configured to couple the bit lines of second memory arrays with first interconnecting layer 514. The second contacts may include a second capacitor contact configured to couple a common electrode of the second capacitors in a memory array with first interconnecting layer 514. In some implementations, the second contacts may further include a shielding contact configured to couple the conductive core between two adjacent second vertical transistors to a common ground.

In some implementations, as shown in FIG. 5F, a pad-out interconnect layer 540 is formed on second semiconductor structure 530. Pad-out interconnect layer 540 can include interconnects formed in one or more ILD layers. In some implementations, the interconnects in pad-out interconnect layer 540 can transfer electrical signals between the semiconductor structures and outside circuits, e.g., for pad-out purposes. Pad-out interconnect layer 540 can include interconnects, e.g., contact pads, and contacts surrounded by dielectric layer. The contact pads, and contacts can include conductive materials including, but not limited to, W, Co, Cu, Al, silicide, or any combination thereof. In one example, contact pad may include Al, and contact may include W. Depending on the thickness of substrate, contact can be an ILV having a depth in the submicron-level (e.g., between 10 nm and 1 μm), or a TSV having a depth in the micron-or tens micron-level (e.g., between 1 μm and 100 μm).

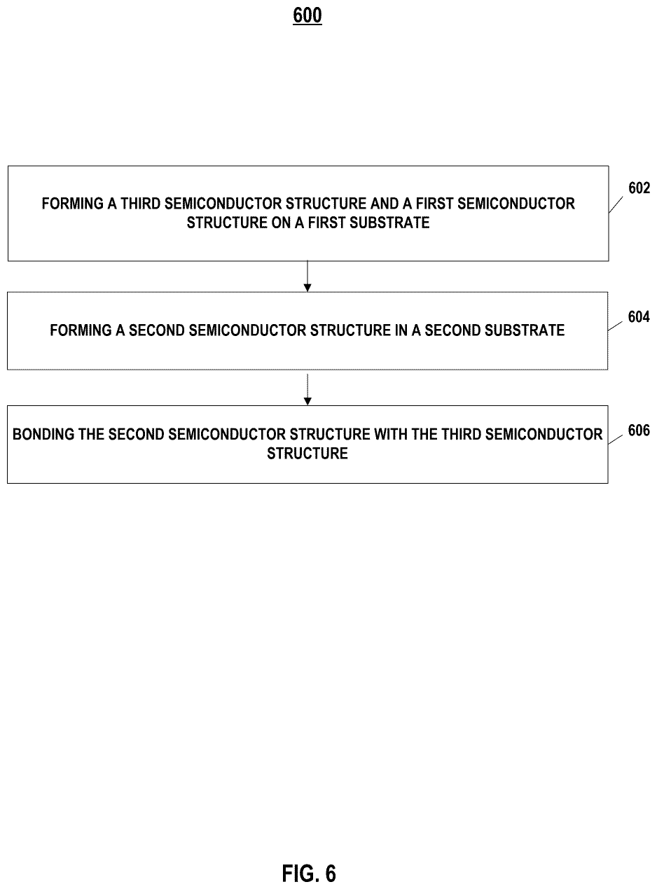

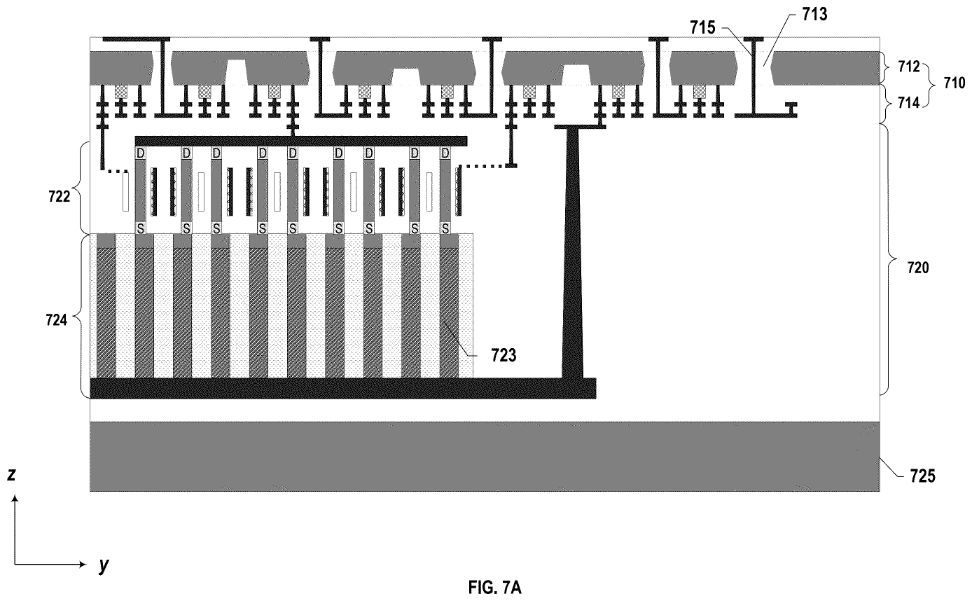

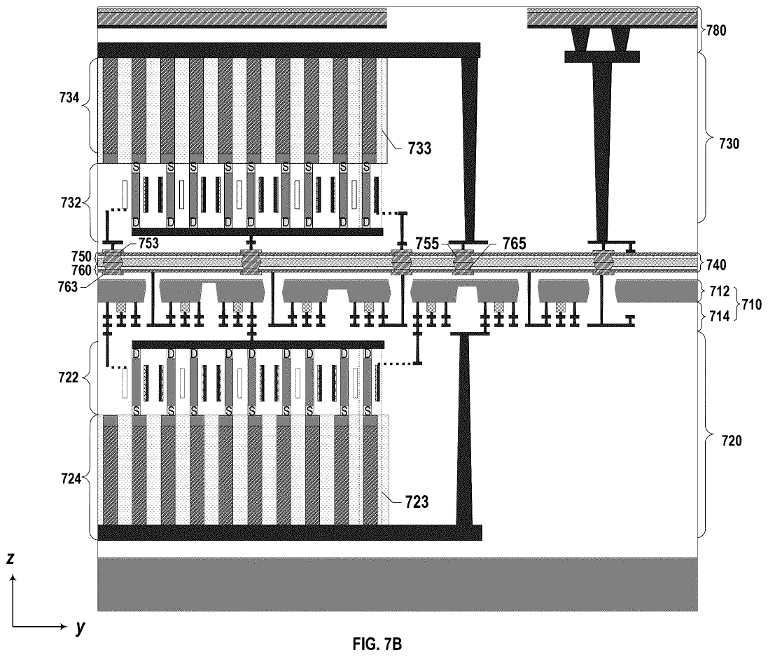

FIG. 6 illustrates a flowchart of a fabricating method 600 for forming a semiconductor structure, according to some implementations of the present disclosure. FIGS. 7A-7C illustrate schematic views of a semiconductor device at certain fabricating stages of method 600 shown in FIG. 6, according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIGS. 6 and 7A, method 600 can start at operation 602, in which a third semiconductor structure 710 and a first semiconductor structure 720 are formed. Third semiconductor structure 710 includes a first peripheral circuit structure and a second peripheral circuit structure on a substrate 712. Third semiconductor structure 710 further includes a first interconnecting layer 714 coupled with the first and second peripheral circuit structures, respectively. In some implementations, third semiconductor structure 710 further includes a plurality of holes 713 throughout substrate 712 and a plurality of vias 715 formed in holes 713. The second peripheral circuit structure would be coupled to a second semiconductor structure through the plurality of vias 715. First semiconductor structure 720 is formed on third semiconductor structure 710 and is coupled with the first peripheral circuit structure through first interconnecting layer 714. First semiconductor structure 720 includes a plurality of first memory cell 723 each including a vertical transistor 722 and a capacitor 724 coupled with corresponding vertical transistor 722. After first semiconductor structure 720 is formed, substrate 712 is thinned, and a carrier substrate 725 is formed covering second semiconductor structure 730 for subsequent process. The fabrication processes of third semiconductor structure 710 and first semiconductor structure 720 may be similar to those described above and will not be repeated here.

As shown in FIGS. 6 and 7B, method 600 can then proceed to operation 604, in which a second semiconductor structure 730 is formed on a separate substrate. Second semiconductor structure 730 may include a plurality of first memory cell 733 each including a vertical transistor 732 and a capacitor 734 coupled with corresponding vertical transistor 732. After first semiconductor structure 720 is formed, substrate 712 is thinned, and a carrier substrate 725 is formed, covering second semiconductor structure 730 for the subsequent process. The fabrication processes of second semiconductor structure 730 may be similar to that described above and will not be repeated here. Referring to FIG. 7B, method 600 can proceed to operation 606, in which second semiconductor structure 730 is bonded with third semiconductor structure 710 at the backside of third semiconductor structure 710.

In some implementations, third semiconductor structure 710 and second semiconductor structure 730 can be bonded together at the bonding interface 740. Bonding interface 740 can be an interface between third semiconductor structure 710 and second semiconductor structure 730 formed by any suitable bonding technologies, such as hybrid bonding, anodic bonding, fusion bonding, transfer bonding, adhesive bonding, and eutectic bonding, to name a few.

Referring to FIG. 7B, bonding interface 740 includes a first bonding structure 750 formed on a bonding surface of first semiconductor structure 720, and a second bonding structure 760 formed on a bonding surface of third semiconductor structure 710. In some implementations, first bonding structure 750 includes at least one dielectric layer covering the bonding surface of second semiconductor structure 730, a first bonding contacts 755 extending through the dielectric layer, and a first conductive pad 753 coupled between the first bonding contacts 755 and second semiconductor structure 730. Second bonding structure 760 includes at least one dielectric layer covering a bonding surface of third semiconductor structure 710, a second bonding contacts 765 extending through the dielectric layer, and a second conductive pad 763 coupled between the second bonding contacts 765 and third semiconductor structure 710. In some implementations, first bonding structure 750 may include a first carbon nitride layer where the first conductive pad 753 is embedded, and second bonding structure 760 may include a second carbon nitride layer where the second conductive pad 763 is embedded. In some implementations, first bonding structure 750 includes a first silicon oxide layer where the first conductive pad 753 is embedded, and the second bonding structure 755 may include a second silicon oxide layer where the second conductive pad 763 is embedded. In some implementations, first bonding contacts 755 are in contact with the second bonding contacts 765 at the bonding interface 740 after the bonding.

In some implementations, third semiconductor structure 710 and second semiconductor structure 730 are directly bonded together, which is also referred to as Wafer-to-Wafer Bonding. Direct bonding is a process where two semiconductor wafers are brought into contact and bonded without the need for any intermediate adhesive or material. Direct bonding relies on atomic-level interactions at the surfaces of the bonding interface, as shown in FIG. 7B. In some implementations, the bonding surfaces of third semiconductor structure 710 and second semiconductor structure 730 are cleaned and then bonded at elevated temperatures (typically 300-400° C.) in the presence of hydrogen. Strong covalent bonds between third semiconductor structure 710 and second semiconductor structure 730 will be created.

In some implementations, third semiconductor structure 710 and second semiconductor structure 730 are bonded together using a thin layer of polymer or adhesive material (such as epoxy, UV-cured resin, or underfill) between them. In some implementations, a thin layer of epoxy or polymer adhesive is applied between the two bonding surfaces of third semiconductor structure 710 and second semiconductor structure 730, followed by curing under heat or UV light to create the bond. In some implementations, third semiconductor structure 710 and second semiconductor structure 730 may be bounded through other bonding approaches, such as Gold-Tin (Au-Sn) Eutectic Bonding, Copper-Copper (Cu-Cu) Bonding, Solder Bonding, and the like. It should be noted that the bonding method described in the present disclosure is illustrative and should not be explained as a limitation of the present disclosure. In some implementations, as shown in FIG. 7B, a pad-out interconnect layer 780 is formed on second semiconductor structure 730. Pad-out interconnect layer 780 can include interconnects formed in one or more ILD layers. In some implementations, the interconnects in pad-out interconnect layer 780 can transfer electrical signals between the semiconductor structures and outside circuits, e.g., for pad-out purposes. The fabrication processes of pad-out interconnect layer 780 may be similar to that described above and will not be repeated here.

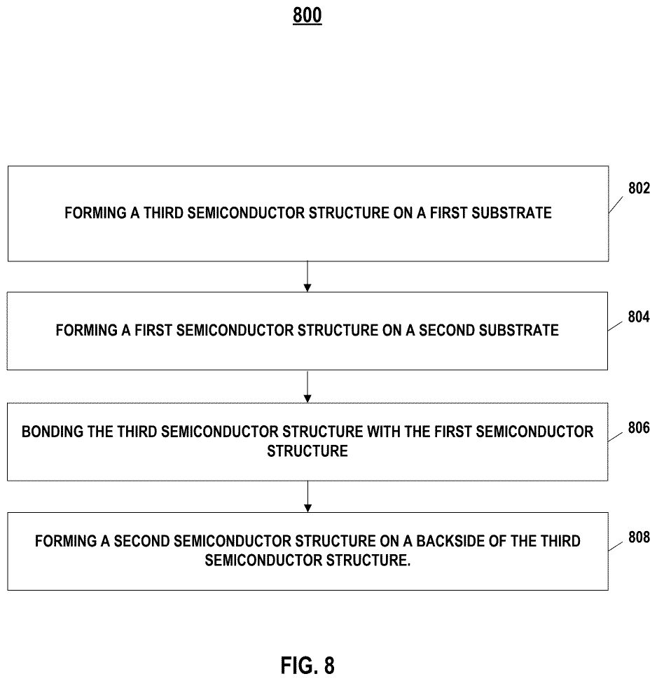

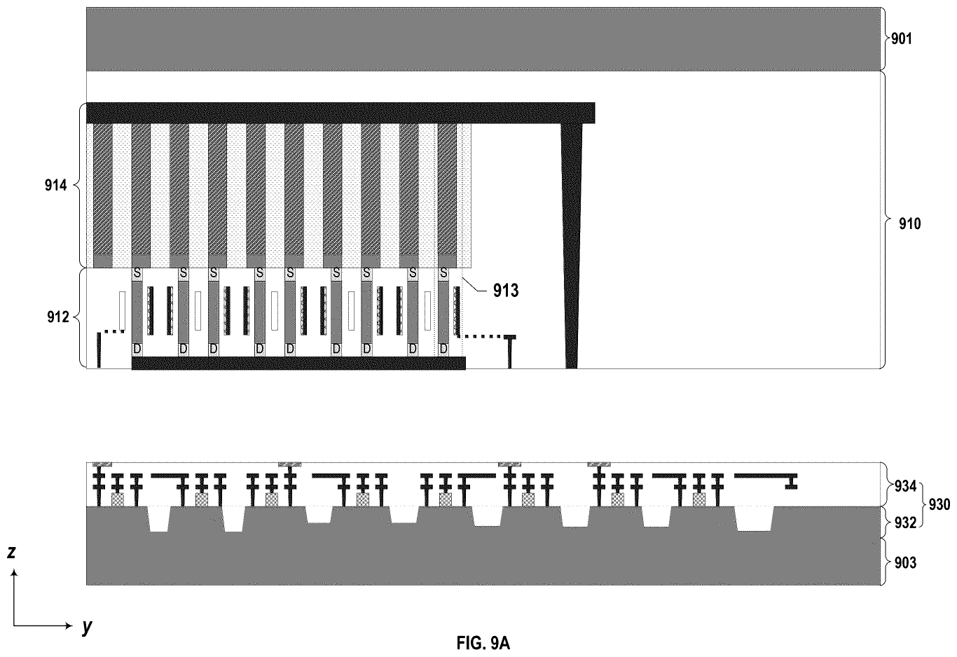

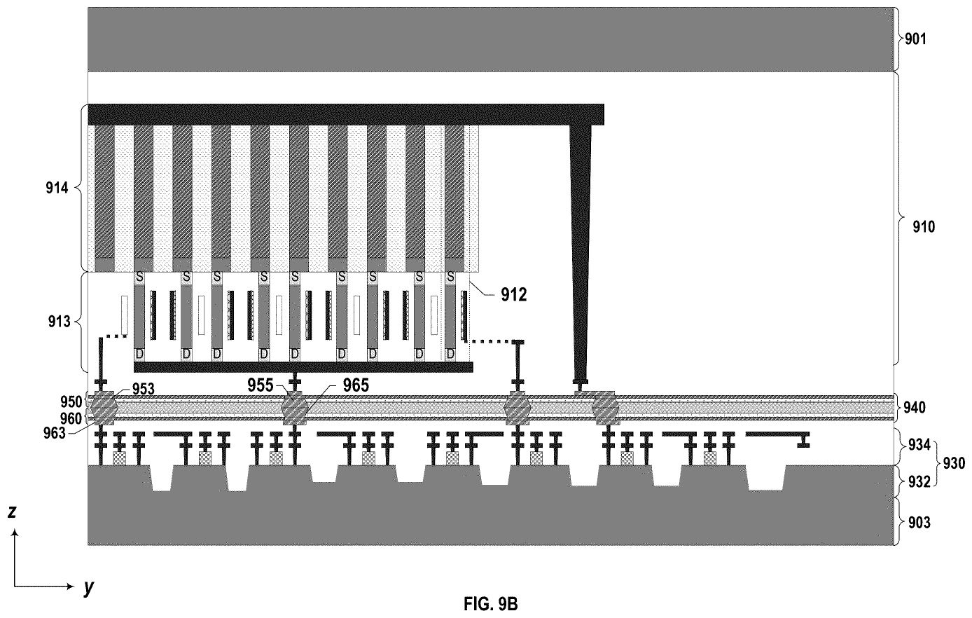

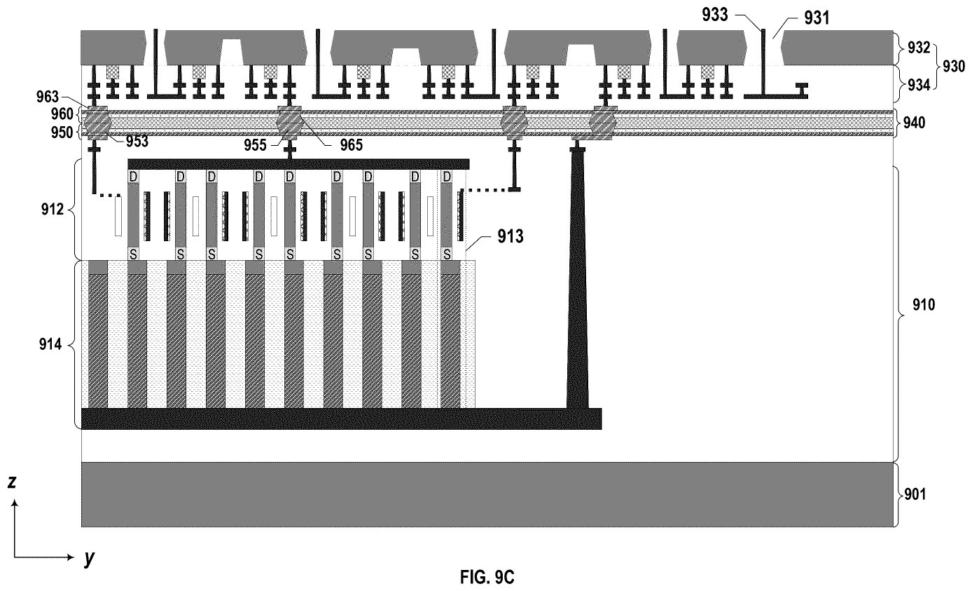

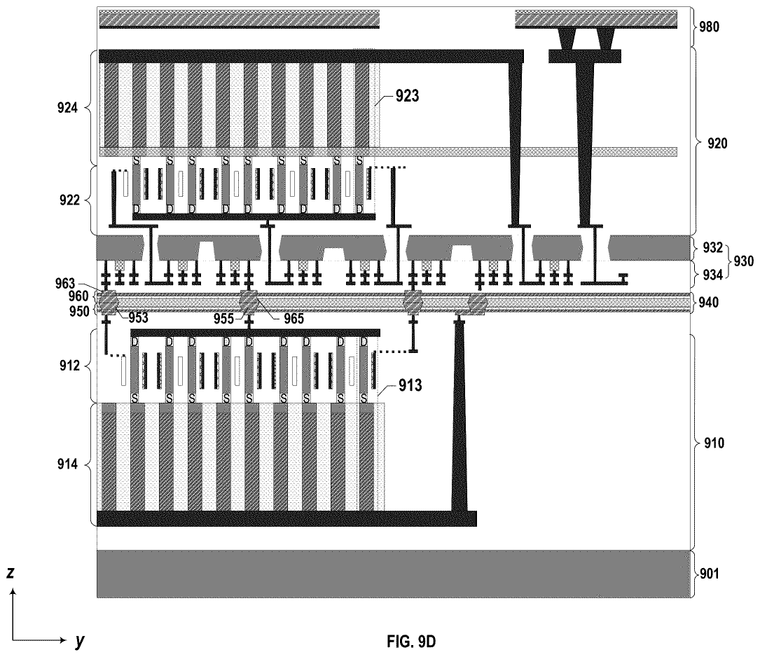

FIG. 8 illustrates a flowchart of a fabricating method 800 for forming a semiconductor structure, according to some implementations of the present disclosure. FIGS. 9A-9D illustrate schematic views of a semiconductor device at certain fabricating stages of the method 800 shown in FIG. 8, according to various implementations of the present disclosure. It is understood that the operations shown in method 800 are not exhaustive and that other operations can be performed as well before, after, or between any of the illustrated operations. Further, some of the operations may be performed simultaneously, or in a different order than shown in FIG. 8.

As shown in FIGS. 8 and 9A, method 800 can start at operation 802, in which a third semiconductor structure 930 is formed on a third substrate 903. Method 800 can then proceed to operation 804, in which a first semiconductor structure 910 is formed on a first substrate 901. Third semiconductor structure 930 includes a first peripheral circuit structure and a second peripheral circuit structure formed on a semiconductor layer 932. Third semiconductor structure 930 further includes a first interconnecting layer 934 coupled with the first and second peripheral circuit structures respectively. First semiconductor structure 910 includes a plurality of first memory cell 913 each including a vertical transistor 912 and a capacitor 914 coupled with corresponding vertical transistor 912. The fabrication processes of first semiconductor structure 910 and third semiconductor structure 930 may be similar to that described above and will not be repeated here.

As shown in FIGS. 8 and 9B, method 800 can proceed to operation 806, in which first semiconductor structure 910 and third semiconductor structure 930 are bonded together at a bonding interface 940.

In some implementations, referring to FIG. 9B, first semiconductor structure 910 is bonded with third semiconductor structure 930 can be bonded together at the bonding interface 940. Bonding interface 940 can be an interface between first semiconductor structure 910 and third semiconductor structure 930 formed by any suitable bonding technologies, such as hybrid bonding, anodic bonding, fusion bonding, transfer bonding, adhesive bonding, eutectic bonding, to name a few.

Referring to FIG. 9B, bonding interface 940 includes a first bonding structure 950 formed on a bonding surface of first semiconductor structure 910, and a second bonding structure 960 formed on a bonding surface of third semiconductor structure 930. In some implementations, first bonding structure 950 includes at least one dielectric layer covering the bonding surface of third semiconductor structure 930, a first bonding contacts 955 extending through the dielectric layer, and a first conductive pad 953 coupled between the first bonding contacts 955 and third semiconductor structure 930. Second bonding structure 960 includes at least one dielectric layer covering a bonding surface of third semiconductor structure 930, a second bonding contacts 965 extending through the dielectric layer, and a second conductive pad 963 coupled between the second bonding contacts 965 and third semiconductor structure 930. In some implementations, first bonding structure 950 may include a first carbon nitride layer where the first conductive pad 953 is embedded, and second bonding structure 960 may include a second carbon nitride layer where the second conductive pad 963 is embedded. In some implementations, first bonding structure 950 includes a first silicon oxide layer where the first conductive pad 953 is embedded, and the second bonding structure 960 may include a second silicon oxide layer where the second conductive pad 963 is embedded. In some implementations, first bonding contacts 955 are in contact with the second bonding contacts 965 at the bonding interface 940 after the bonding.

In some implementations, third semiconductor structure 930 and first semiconductor structure 910 are directly bonded together, which is also referred to as Wafer-to-Wafer Bonding. Direct bonding is a process where two semiconductor wafers are brought into contact and bonded without the need for any intermediate adhesive or material. Direct bonding relies on atomic-level interactions at the surfaces of the bonding interface, as shown in FIG. 9B. In some implementations, the bonding surfaces of second semiconductor structure 920 and first semiconductor structure 910 are cleaned and then bonded at elevated temperatures (typically 300-400° C.) in the presence of hydrogen. Strong covalent bonds between third semiconductor structure 930 and first semiconductor structure 910 will be created. In some implementations, third semiconductor structure 930 and first semiconductor structure 910 are bonded together through other bonding approaches, such as adhesive bonding, Gold-Tin (Au-Sn) Eutectic Bonding, Copper-Copper (Cu-Cu) Bonding, Solder Bonding, and the like. It should be noted that the bonding method described in the present disclosure is illustrative and should not be explained as a limitation of the present disclosure.

Referring to FIG. 9C, in some implementations, method 800 further includes thinning or removing substrate 903 and forming a plurality of holes 931 throughout semiconductor layer 932. A plurality of vias 933 are formed in the holes 931 correspondingly to couple the first interconnecting layer 934 out. In some implementations, substrate 903 may be removed or thinned using a process of mechanical grinding, CMP, deep reactive ion etching (DRIE), laser ablation, plasma etching, chemical etching, etc. It should be noted that the thinning method described in the present disclosure is illustrative and should not be explained as a limitation of the present disclosure.

As shown in FIGS. 8 and 9D, method 800 can proceed to operation 808, in which a second semiconductor structure 920 is formed on the backside of third semiconductor structure 930. Second semiconductor structure 920 includes a plurality of second memory cells 923 each including a vertical transistor 922 and a capacitor 924 coupled with corresponding vertical transistor 922. In some implementations, as shown in FIG. 9D, a pad-out interconnect layer 980 is formed on second semiconductor structure 920. Pad-out interconnect layer 980 can include interconnects formed in one or more ILD layers. In some implementations, the interconnects in pad-out interconnect layer 980 can transfer electrical signals between the semiconductor structures and outside circuits, e.g., for pad-out purposes. Pad-out interconnect layer 980 can include interconnects, e.g., contact pads, and contacts surrounded by a dielectric layer. The contact pads, and contacts can include conductive materials including, but not limited to, W, Co, Cu, Al, silicide, or any combination thereof. The fabrication processes of second semiconductor structure 920 and pad-out interconnect layer 980 may be similar to that described above and will not be repeated here.

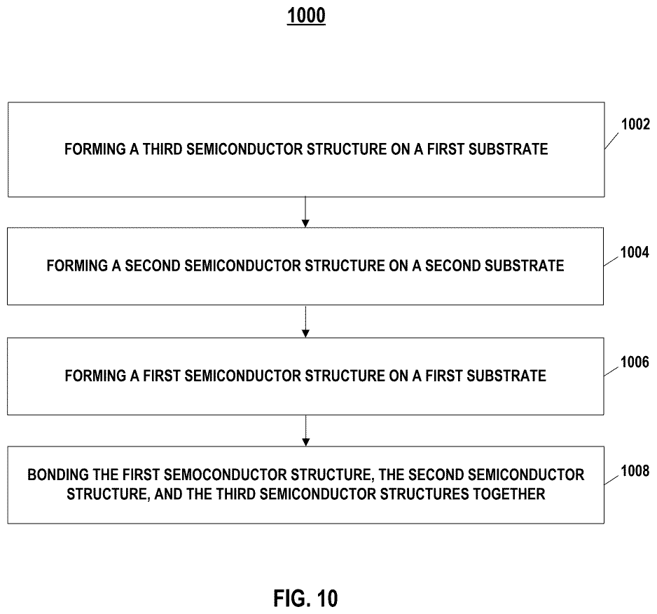

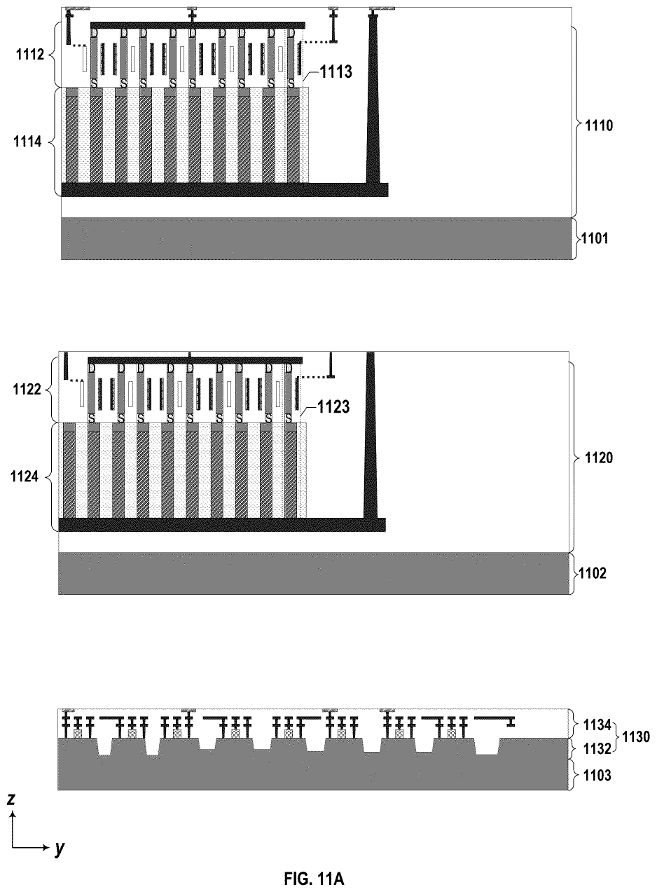

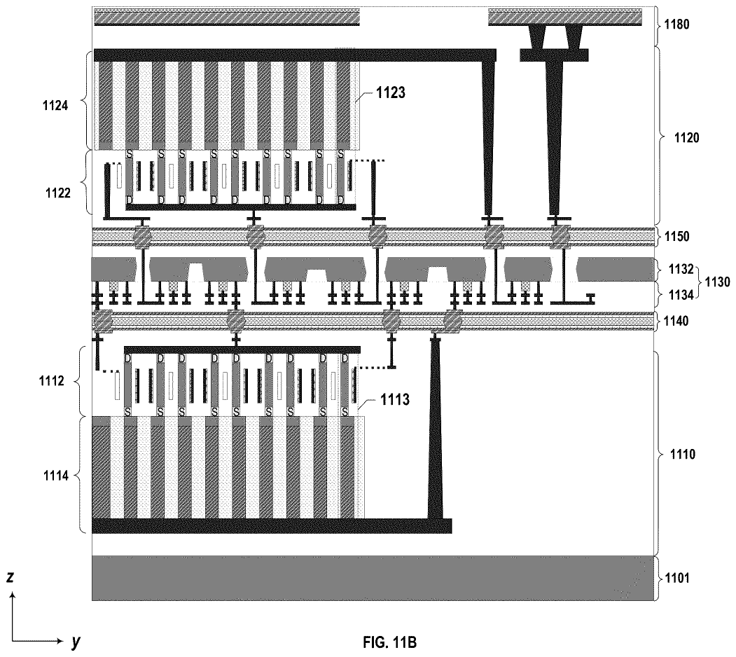

FIG. 10 illustrates a flowchart of a fabricating method 1000 for forming a semiconductor structure, according to some implementations of the present disclosure. FIGS. 11A-11B illustrate schematic views of a semiconductor device at certain fabricating stages of the method 1000 shown in FIG. 10 according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIGS. 10 and 11A, method 1000 may start at either one of operations 1002, 1004, and 1006, in which a first semiconductor structure 1110 is formed on a first substrate 1101, a second semiconductor structure 1120 is formed on a first substrate 1102, and a third semiconductor structure 1130 is formed on a third substrate 1103. The three semiconductor structures may be formed separately and independently, ensuring that there is no interference from one structure to another during the fabrication processes.

In some implementations, first semiconductor structure 1110 includes a plurality of first memory cell 1113 each including a vertical transistor 1112 and a capacitor 1114 coupled with corresponding vertical transistor 1112. Second semiconductor structure 1120 includes a plurality of first memory cell 1123 each including a vertical transistor 1122 and a capacitor 1124 coupled with corresponding vertical transistor 1122. Third semiconductor structure 1130 may include a first peripheral circuit structure and a second peripheral circuit structure formed on a semiconductor layer 1132. Third semiconductor structure 1130 further includes a first interconnecting layer 1134 coupled with the first and second peripheral circuit structures respectively. The fabrication processes of the three semiconductor structures may be similar to those described above and will not be repeated here.

As shown in FIGS. 10 and 11B, method 1000 may proceed to operation 1008, in which first semiconductor structure 1110 and second semiconductor structure 1120 are bonded to two sides of third semiconductor structure 1130 respectively. In some implementations, before bonding together, third substrate 1103 is thinned or removed to generate a bonding interface. A plurality of vias are formed throughout semiconductor layer 1132 to couple with first interconnecting layer 1134. In some implementations, first semiconductor structure 1110 is bonded to a first side of third semiconductor structure 1130 at a first bonding interface 1140, and second semiconductor structure 1120 is bonded to a second side of third semiconductor structure 1130 at a second bonding interface 1150. The detailed bonding processes may be similar to the processes described above and will not be repeated. In some implementations, as shown in FIG. 11B, a pad-out interconnect layer 1180 is formed on second semiconductor structure 1120. Pad-out interconnect layer 1180 can include interconnects formed in one or more ILD layers. In some implementations, the interconnects in pad-out interconnect layer 1180 can transfer electrical signals between the semiconductor structures and outside circuits, e.g., for pad-out purposes. The fabrication processes of pad-out interconnect layer 1180 may be similar to that described above and will not be repeated here.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described implementations but should be defined only in accordance with the following claims and their equivalents.

What is claimed is:

1. A semiconductor device, comprising:
a first semiconductor structure comprising first memory cells each having a first transistor and a first storage unit coupled to the first transistor;
a second semiconductor structure comprising second memory cells each having a second transistor and a second storage unit coupled to the second transistor; and
a third semiconductor structure located between the first semiconductor structure and the second semiconductor structure in a first direction; wherein
the third semiconductor structure comprises:
a first peripheral circuit structure formed on a semiconductor layer and coupled to the first semiconductor structure, and
a second peripheral circuit structure formed on the semiconductor layer and coupled to the second semiconductor structure.

2. The semiconductor device of claim 1, wherein
the first peripheral circuit structure is formed on a first side of the semiconductor layer;
the second peripheral circuit structure is formed on a second side of the semiconductor layer; and
the second side of the semiconductor layer is opposite to the first side of the semiconductor layer.

3. The semiconductor device of claim 2, wherein
the first semiconductor structure further comprises a plurality of first contacts coupled between the first peripheral circuit structure and the first memory cells; and
the second semiconductor structure further comprises a plurality of second contacts coupled between the second peripheral circuit structure and the second memory cells; wherein the first contacts and the second contacts are misaligned along the first direction.

4. The semiconductor device of claim 1, wherein:
the first peripheral circuit structure and the second peripheral circuit structure are formed on a first side of the semiconductor layer.

5. The semiconductor device of claim 4, wherein
the first semiconductor structure further comprises a plurality of first contacts coupled between the first memory cells and the first peripheral circuit structure;
the second semiconductor structure further comprises a plurality of second contacts coupled with the second memory cells;
the third semiconductor structure further comprises a plurality of vias throughout the semiconductor layer and coupled between the second contacts and the second peripheral circuit structure; and
the first contacts and the second contacts are misaligned along the first direction.

6. The semiconductor device of claim 1, further comprising:
a plurality of first contacts coupled between the first semiconductor structure and the third semiconductor structure; wherein a first lateral dimension of a first end of the first contacts away from the third semiconductor structure is greater than a second lateral dimension of a second end of the first contacts close to the third semiconductor structure.

7. The semiconductor device of claim 1, further comprising:
a first bonding structure located between the first semiconductor structure and the third semiconductor structure; and
a plurality of first contacts coupled between the first semiconductor structure and the first bonding structure; wherein a first lateral dimension of a first end of the first contacts away from first bonding structure is smaller than a second lateral dimension of a second end of the first contacts close to the first bonding structure.

8. The semiconductor device of claim 1, further comprising:
a second bonding structure located between the second semiconductor structure and the third semiconductor structure; and
a plurality of second contacts coupled between the second semiconductor structure and the second bonding structure; wherein a first lateral dimension of a first end of the second contacts away from the second bonding structure is smaller than a second lateral dimension of a second end of the second contacts close to the second bonding structure.

9. The semiconductor device of claim 1, wherein
the first transistor or the second transistor comprises a channel layer extending along the first direction and a gate structure coupled to the channel layer, and a leakage value of the channel layer is lower than a pico-ampere.

10. The semiconductor device of claim 9, wherein
a thickness of the channel layer in a second direction is smaller than a width of the channel layer in a third direction, the first direction, the second direction, and the third direction are perpendicular to each other.

11. The semiconductor device of claim 10, wherein
a ratio between the width of the channel layer and the thickness of the channel layer ranges from 10 to 500.

12. The semiconductor device of claim 9, wherein
the first transistor or the second transistor is a single-gate transistor in which the gate structure is located at one side of the channel layer in a plan view; and
the channel layer comprises:
a first portion extending along the first direction, and
a second portion extending from an end of the first portion along a second direction; wherein
the second portion is coupled with a corresponding storage unit, and
the first direction and the second direction are perpendicular to each other.

13. A method for forming a semiconductor device, comprising:
forming a third semiconductor structure comprising a first peripheral circuit structure and a second peripheral circuit structure on a semiconductor layer;
forming a first semiconductor structure comprising first memory cells each having a first transistor and a first storage unit coupled to the first transistor, the first semiconductor structure being coupled to the first peripheral circuit structure on a first side of the third semiconductor structure; and
forming a second semiconductor structure comprising second memory cells each having a second transistor and a second storage unit coupled to the second transistor, the second semiconductor structure being coupled to the second peripheral circuit structure on a second side of the third semiconductor structure; wherein the third semiconductor structure is located between the first semiconductor structure and the second semiconductor structure in a first direction.

14. The method of claim 13, wherein forming the first semiconductor structure comprises:
forming a first inter-structure isolation layer on a first side of the semiconductor layer;
forming the first memory cells on the first inter-structure isolation layer; and
forming a plurality of first contacts coupled between the first memory cells and the first peripheral circuit structure.

15. The method of claim 14, wherein forming the second semiconductor structure comprises:
forming a second inter-structure isolation layer on a second side of the semiconductor layer;
forming the second memory cells on the second inter-structure isolation layer; and
forming a plurality of second contacts coupled between the second memory cells and the second peripheral circuit structure; wherein the first contacts and the second contacts are misaligned along the first direction.

16. The method of claim 15, wherein the semiconductor layer is formed on a third substrate, and forming the second semiconductor structure comprises:
forming the second semiconductor structure on a second substrate; and
bonding the second substrate with a second side of the third substrate to form a second bonding structure.

17. The method of claim 13, wherein forming the first semiconductor structure comprises:
forming the first semiconductor structure on a first substrate;
forming the second semiconductor structure on a second substrate;
forming the semiconductor layer on a third substrate;
bonding the first substrate with a first side of the third substrate through a plurality of first bonding contacts to form a first bonding structure; and
bonding the second substrate with a second side of the third substrate through a plurality of second bonding contacts to form a second bonding structure.

18. The method of claim 13, wherein forming the first peripheral circuit structure and the second peripheral circuit structure on the semiconductor layer comprises:
forming the first peripheral circuit structure on a first side of the semiconductor layer; and
forming the second peripheral circuit structure on a second side of the semiconductor layer.

19. The method of claim 13, wherein forming the first peripheral circuit structure and the second peripheral circuit structure on the semiconductor layer comprises:
forming the first peripheral circuit structure and the second peripheral circuit structure on a first side of the semiconductor layer; and
forming a plurality of vias throughout the semiconductor layer and coupled between the second peripheral circuit structure and the second semiconductor structure.

20. A semiconductor device, comprising:
a first semiconductor structure comprising a first array of memory cells;
a second semiconductor structure comprising a second memory cells; and
a third semiconductor structure located between the first semiconductor structure and the second semiconductor structure in a first direction; wherein
the third semiconductor structure comprises:
a third substrate,
a first peripheral circuit structure on the third substrate and coupled to the first semiconductor structure, and
a second peripheral circuit structure on the third substrate and coupled to the second semiconductor structure.
